(19) United States
(12) Patent Application Publication
(10) Pub. No.: US 2004/0258848 A1
(43) Pub. Date: Dec. 23, 2004

(54) Method and apparatus for processing a substrate

(76) Inventors: Akira Fukunaga, Tokyo (JP); Daisuke Takagi, Tokyo (JP); Satoshi Morikami, Tokyo (JP)

Correspondence Address: WENDEROTH, LIND & PONACK, L.L.P., 2033 K STREET N. W., SUITE 800, WASHINGTON, DC, 20006-1021, US

(21) Appl. No.: 10/850,372

(22) Filed: May 21, 2004

(30) Foreign Application Priority Data
May 23, 2003 (JP) 2003-146867
Aug. 8, 2003 (JP) 2003-206910

(51) Int. Cl. H01L 21/00; B05C 3/00; B05D 1/18

(52) U.S. Cl. 427/430.1; 427/437; 118/400

(57) ABSTRACT

A method for processing a substrate having a metal layer formed on a surface of the substrate is set forth. The method first preprocesses a surface of the metal layer, deposits a protective film selectively on a surface of the metal layer by an electroless plating process, cleans the substrate after depositing the protective film, and dries the substrate after cleaning. These processes are repeated a plurality of times to process a plurality of substrate. The deposition rate in the deposition process is 10˜600 Å/min, and a variance of deposition rate for the plurality of substrate is controlled within ±10%.

### BACKGROUND OF THE INVENTION

1. Field of the Invention

The present invention relates to a method and apparatus for plating a substrate, and more particularly to a method and apparatus for depositing a functional film by an electroless plating process on a bottom, side, or exposed top surface of a filled-in interconnect deposited on the substrate, which is formed by filling a conductor material such as copper, silver etc. in a fine recess formed on the surface of the substrate. The functional film comprises, for example, a conductive film capable of preventing thermal diffusion of the interconnect material into an interlayer insulative film or enhancing tight bonding between the interconnect and interlayer insulative film, or a protective film such as a magnetic film covering the interconnect.

2. Description of the Related Art

A damascene process is used as an interconnect forming process, in which, metal (conductor) is filled into a wiring trench or contact hole. In this processing technique, a metal material such as aluminum, copper, or silver or an alloy thereof is filled in a trench or hole which is readily formed on the interlayer insulative film, and thereafter, the excess metal is removed and the surface is planarized by a chemical mechanical polishing (CMP) process.

In order to promote reliability of the conventional interconnect using copper, for example, a barrier film is deposited to cover the bottom and side surfaces of the interconnect for preventing thermal diffusion of the interconnect material (copper) or improving resistance against electromigration, or an oxidation inhibiting film is deposited for preventing oxidation of the interconnect in an oxidizing atmosphere in the following stages of manufacturing a semiconductor device having layered wiring structure and layered insulative films. As to the conventional barrier layer material, metals such tantalum, titanium, or tungsten or nitrides thereof are used, and as to the oxidation inhibiting film, silicon nitride etc. is used.

Lately, studies are underway for using Co alloys or Ni alloys for forming a plating film to selectively cover the bottom, side, or exposed top surface of the interconnect for preventing thermal diffusion, electromigration or oxidation. Also, in manufacturing nonvolatile storage devices, use of magnetic films made of Co alloys or Ni alloys is proposed to surround the writing interconnect for suppressing increase of writing current due to micronization of the device. One method of forming these Co alloys or Ni alloys is electroless plating.

FIG. 1 shows, for example, a process for manufacturing a semiconductor device, where a substrate W such as semiconductor wafer is formed with a deposited insulative film 2 made of SiO₂ etc. on the surface. Then, a fine recess 4 is formed on the insulative film 2 and a barrier layer 6 is deposited with a TaN etc. on the recess 4 surface. Then, a copper film, for example, is deposited by plating to fill the recess 4, and the surface of the substrate W is further planarized by a CMP process to form an interconnect 8 made of copper within the insulative film 2. Then, the surface of the copper interconnect 8 is selectively covered by a protective film (capping member) 9 made of a Co—W—F alloy deposited through electroless plating.

A first process for selectively forming the protective film 9 by a conventional electroless plating is removing interconnect 8 metal oxide film etc. from the interconnect 8 surface to be processed by immersing the substrate W, after a CMP process, in a dilute sulfuric acid at a room temperature for about one minute. Then, the substrate surface is cleaned with a cleaning liquid such as deionized water and is immersed in a mixed solution of PdCl₂/HCl, for example, at a room temperature for one minute to apply Pd as a catalyst on the exposed surface of the interconnect 8 to activate the same. The substrate surface is rinsed with a rinsing liquid such as deionized water, and immersed in a Co—W—P plating solution at a temperature of 80° C. for about 120 seconds to selectively electroless plating a Co—W—P alloy protective film 9 on the activated interconnect 8 surface.

However, electroless plating has a short history of application to the field of electronic materials and a large part is still at a trial and error stage. Application to the field of electronic materials claims extremely harsh requirements regarding film quality or repeatability of film thickness compared to the conventional application field In order to fulfill the requirement, a strict regulation of plating solution is necessary.

When forming an interconnect 8 plating film (capping member) made of a Co—W—P alloy etc., it is necessary to deposit a relatively thin film with a good repeatability. On the other hand, the plating solution for electroless plating contains many compositions, for example, Co ions or Ni ions, tungstic acid ions and/or tungsten phosphoric acid ions, hypophosphorous acid ions and/or alkylamineborane such as dimethylamineborane, a chelating agent, a pH adjuster or alkalis, and is generally used by being heated. Thus, it is desirable to measure these compositions or factors and control them within an allowable range.

### SUMMARY OF THE INVENTION

The object of the present invention is to provide a method and apparatus which can deposit a high quality plating film with a good repeatability, without deteriorating resistance property The other object of the invention is to provide a method and apparatus which can manufacture semiconductor device or the like which is electrolessly plated with a good repeatability within a substrate surface or among different substrates with a high yield.

The present invention for solving the above mentioned problem is a method for processing a substrate having a metal layer formed on a surface of the substrate comprising: preprocessing a surface of the metal layer; depositing a protective film selectively on a surface of the metal layer by an electroless plating process; cleaning the substrate after depositing the protective film; drying the substrate after cleaning; and repeating the preprocessing, depositing, cleaning, and drying a plurality of times to process a plurality of substrate, wherein deposition rate in the deposition process is 10˜600 Å/min, and a variance of deposition rate for the plurality of substrate is within 110.

The deposition rate directly governs the production rate so that an excessively small deposition rate is not acceptable, while an excessively large production rate cannot provide uniform protective films with a good repeatability. The protective film thickness is required to be at least 50% thick for establishing its object and also requires to be less than 500 Å for restricting interconnect resistance raise to a minimum. A suitable deposition rate is 10˜600 Å per minute in general, 10˜200 Å per minute preferably, and 20˜100 Å per minute more preferably.

If variance of the thickness of the plated film is large between the substrates, variance is also large for expected protective function or interconnect resistance which leads to allowing narrower margins for the following process steps. Thus, it is necessary to control variance of the deposition rate between the substrates within ±10% generally, and within ±5% preferably The metal layer may be an exposed surface of a filled-in interconnect deposited on bottom and side surfaces of a trench formed on a surface of the substrate, or on a surface of the substrate.

The metal layer may comprise copper, a copper alloy, silver, or a silver alloy, Ti, Ta, W, Ru, and a compound thereof. These materials can provide a highly integrated device so as to facilitate accelerating and densification of semiconductor devices.

The protective film may comprise cobalt, a cobalt alloy, nickel, or a nickel alloy. These materials can provide a protective film covering the interconnect to protect the same.

The protective film may comprise at least (1) cobalt or nickel, (2) tungsten or molybdenum, and (3) phosphorous or boron. These materials can provide a relatively small deposition rate and is advantageous for depositing a thin film. These are also advantageous because the plating solution is stable and provides an easy composition control as well as a good repeatability.

The protective film may be deposited by making the substrate contact with a plating solution for adjusting the temperature of the substrate at 70˜90° C. Among various kinds of electroless plating solutions for depositing protective films on the interconnect surface, every one of them requires heating, so that plating solutions of less than 70° C. cannot provide adequate deposition rate. However, plating solutions of more than 90° C. cannot provide a stable deposition process due to an excessively high water evaporation as well as excessively high deposition rate. Therefore, controlling the solution temperature between 70° C. and 90° C. can provide stable and highly repeatable deposition process with 10˜200 Å deposition rate per minute.

Variance of the temperature of the plating solution may be controlled within ±2° C. Deposition rate of the protective film in an electroless plating process depends largely on the plating solution temperature, and small temperature difference influences largely to the deposition rate. Therefore, controlling the temperature variance within ±2° C. and more preferably ±1° C. can also control the deposition rate among the substrates ±10% generally, and ±5% preferably.

The decrease of the plating solution due to evaporation may be compensated to control the decrease of plating solution within 10% of initial quantity of the plating solution.

The decrease of the plating solution may be quantified by measuring liquid level within a plating solution reservoir tank, and shortage of water may be compensated by supplying deionized water to the plating solution. In order to manage the solution quantity control, it is preferable to replenish deionized water to compensate loss of the solution by measuring the solution surface level within the plating solution reservoir tank.

The concentration of metal ions within the plating solution such as Co ions or Ni ions should be controlled within the level of 0.01˜0.1 mol/L and variance of concentration is controlled within ±20%. When applying Co or Ni alloy film as the protective film, a plating solution containing Co ions or Ni ions is used and the deposition rate depends on the metal ion concentration to a certain extent. Thus, by controlling the metal ion concentration within the electroless plating solution not less than 0.01 mol/L and not more than 0.1 mol/L, the deposition rate can be controlled 10˜200 Å per minute and the deposition is performed with a good repeatability.

Variance of Co ion or Ni ion concentration may be maintained within ±20%. The deposition rate for the protective film during the electroless plating process does not depend on the metal ion concentration in the plating solution so much when compared to the plating solution temperature. Thus, by controlling variance of Co or Ni ion concentration within ±20% generally, and ±10% preferably, the deposition rate variance among different substrates can be controlled within ±10% generally, and ±5% preferably.

By measuring the Co or Ni ion concentration within the plating solution by an absorptiometry analyzer, an ion chromatograph analyzer, a capillary electrophoresis analyzer, or a chelatometric titration analyzer, and replenishing solutions containing these metal ions to supply necessary metal ions based on the measurement, metal ion concentration within the plating solution can be controlled within a certain range.

The electroless plating may be performed by using a plating solution containing a concentration of tungstic acid or molybdic acid ions and/or tungsten phosphoric acid or molybdenum phosphoric acid ions of 1.5˜30.0 g/L as converted to tungsten or molybdenum.

Variance of the tungsten or molybdenum converted concentration is controlled within ±40%.

The tungsten or molybdenum converted concentration may be measured by a capillary electrophoresis analyzer, or calculated from Co ion or Ni ion consumption, and shortage of tungsten or molybdenum converted concentration may be compensated by replenishing a solution containing tungstic acid or molybdic acid ions and/or tungsten phosphoric acid or molybdenum phosphoric acid ions.

The electroless plating may be performed by using a plating solution containing hypophosphorous acid ions, alkylamineborane such as dimethylamineborane, and/or NaBH₄ of 0.05˜0.3 mol/L. When applying an alloy film containing Co and Ni as the protective film, a plating solution containing hypophosphorous acid ions, alkylamineborane, and/or NaBH₄ as a reducing agent is generally used. More than a certain amount of these reducing agents does not affect the deposition rate, and excessive amount of concentration extensively decreases concentration within the deposited protective film to negate its protective function. Thus, it is preferable to control the hypophosphorous acid ion, alkylamineborane, and/or NaBH₄ concentration within the electroless plating solution not less than 0.05 mol/L and not more than 0.3 mol/L to control the deposition rate 10˜200 Å per minute and deposit the film with a good repeatability.

Variance of the hypophosphorous acid ion, alkylamineborane, and/or NaBH₄ concentration may be controlled within ±40%. As described above, dependency of the deposition rate for the protective film during the electroless plating process on the reducing agent concentration in the plating solution is relatively small By controlling variance of the hypophosphorous acid ion, alkylamineborane, and/or NaBH₄ concentration within ±40% generally, and ±20% preferably, the deposition rate variance among different substrates can be controlled within ±10% generally, and ±5% preferably.

The hypophosphorous acid ion, alkylamineborane, and/or NaBH₄ concentration may be measured by an oxidation-reduction titration analyzer or a capillary electrophoresis analyzer shortage of the hypophosphorous acid ion, alkylamineborane, and/or NaBH₄ concentration may be compensated by replenishing a solution containing hypophosphorous acid ions and/or alkylamineborane, and/or NaBH₄ so as to control the concentrations of these components within a certain range.

The electroless plating may be performed by using a plating solution containing a chelating agent of 0.05˜0.5 mol/L. When applying an alloy film containing Co and Ni as the protective film, a plating solution containing a chelating agent is generally used and the deposition rate depends on the chelating agent concentration to a certain extent. Thus, it is preferable to control the chelating agent concentration within the electroless plating solution not less than 0.05 mol/L and not more than 0.5 mol/L to control the deposition rate 10˜200 Å per minute and deposit the film with a good repeatability.

Variance of the chelating agent concentration may be controlled within ±30%. Dependency of the deposition rate for the protective film during the electroless plating process on the chelating agent concentration in the plating solution is relatively small similarly to W or Mo ion concentration. Thus, by controlling variance of the chelating agent concentration within ±30% generally, and ±15% preferably, the deposition rate variance among different substrates can be controlled within ±10% generally, and ±5% preferably.

The chelating agent concentration may be measured by a chelatometric titration analyzer or a capillary electrophoresis analyzer, and shortage of aid chelating agent concentration may be compensated by replenishing a solution containing the chelating agent, so that the chelating agent concentration within the plating solution can be controlled within a certain range.

The electroless plating may be performed by using a plating solution containing a pH buffer and an alkaline agent, and pH of the plating solution may be set 8˜10, When applying an alloy film containing Co and Ni as the protective film, a plating solution containing a pH buffer and an alkaline agent is generally used and the deposition rate is likely to largely depend on the pH value. Thus, it is necessary to control pH of the electroless plating solution 8˜10 generally, and 8.5˜9.5 preferably, to control the deposition rate 10˜200 Å per minute and deposit the film with a good repeatability.

Variance of pH may be controlled within ±0.2. Dependency of the deposition rate for the protective film during the electroless plating process on pH in the plating solution is large so that it is necessary to control variance of pH of the electroless plating solution within ±0.2 generally, and ±0.05 preferably, to control the deposition rate variance among different substrates W within ±10% generally, and ±5% preferably.

By measuring pH of the plating solution by an electrode method or neutralization titration, and replenishing solutions containing pH regulator to correct pH fluctuation based on the measurement, pH of the plating solution can be controlled within a certain range

The deposition rate of the protective film may be measured in the electroless plating process. This allows to confirm that the actual deposition rate is in conformity with the predetermined value. This measurement process can be performed by immersing a quartz resonator in the plating bath, whose oscillation frequency attenuates as electroless plating film deposits on the quartz resonator. The protective films are generally very thin, and narrow control of the film thickness variance requires a method for measuring the deposition rate with a high sensitivity and high precision. By immersing the quartz resonator within the plating bath, these requirements can be fulfilled.

The process time for plating may be adjusted based on measured result of the deposition rate. By increasing or decreasing the process time when the measured thickness differs from the anticipated, for example, this process enables to form a plating film of a predetermined thickness with a good repeatability.

Another aspect of the present invention is an apparatus for processing a substrate having a filled-in interconnect formed on a surface of the substrate, which has bottom and side surfaces or an exposed surface. The apparatus comprises: a preprocessing unit for preprocessing a surface of the substrate; an electroless plating unit for depositing a protective film selectively on the bottom and side surfaces or the exposed surface of the filled-in interconnect by an electroless plating process while deposition rate in the deposition process is controlled 10˜600 Å/min, and a variance of deposition rate for the substrate is controllable within ±10%.

The electroless plating unit may comprise a liquid temperature sensor for sensing a plating solution and a liquid temperature control portion for controlling temperature of the plating solution. The electroless plating unit may comprise a plating solution reservoir tank for reserving a plating solution, and a liquid level sensor for measuring decreased amount of the plating solution due to evaporation by measuring liquid surface level of the plating solution.

The apparatus may further comprise a plating solution composition analyzer for analyzing composition of a plating solution contained in the electroless plating unit.

The apparatus may further comprise a component supply unit for supplying a component in short within a plating solution contained in the electroless plating unit.

The apparatus may further comprise a deposition rate measuring portion for measuring deposition rate in the electroless plating process.

In another aspect of the present invention, a method of processing a substrate comprises: preprocessing a surface of the substrate; depositing a metal or alloy film on at least a part of a surface of the substrate by an electroless plating process using a plating solution; cleaning the substrate after depositing the film; drying the substrate after cleaning; and supplying at least three supply solutions consisting of a deionized water, a bath solution containing necessary components for plating, and a makeup solution containing at least one effective component necessary for plating, wherein the at least three supply solutions are supplied while each supply amount is individually controlled.

In order to control the film property or film thickness constant, it is necessary to maintain the composition of effective components within the plating solution. In the electroless plating process, various factors function to fluctuate quality and quantity of the plating solution as follow.

1. Deionized water used for rinsing the substrate in a preprocess and is brought to the plating vessel.

2. Water loss due to evaporation caused by heating of the plating solution.

3. Plating solution deposited on the substrate W and brought out of the plating vessel.

4. Plating solution consumed for analysis for plating solution concentration regulation.

5. Plating solution brought out of the system due to temporary maintenance operation such as exchange of filters.

Therefore, in order to compensate the fluctuation of qualities and quantities of the plating solution due to the above mentioned factors by supplying solutions such as deionized water, a bath solution containing all or major necessary effective components at a prescribed concentration, or a makeup solution containing an individual or plural effective components for plating to the plating solution.

The bath solution may be supplied subsequently after the deionized water is supplied. For example, by calculating accumulated plating solution for brought-out amount and consumed amount for solution analysis, and by subtracting those, the amount of deionized water supply is determined. The calculated accumulated plating solution can be used as it is for determining bath solution supply to avoid further necessity of calculation. Also, by supplying bath solution subsequently after the deionized water is supplied, the plating solution quantity is securely returned to the initial level, facilitating an easy control of plating solution.

The makeup solution may be supplied subsequently after the deionized water and/or the bath solution is supplied. Concentration adjustment using makeup solutions are inherently for compensating effective components consumed for the plating reaction. Thus, supplying deionized water for compensating evaporation loss or bath solution for brought-out loss in advance to readjust losses other than the consumed by plating, the number of adjustment can be decreased. For that reason, it is preferable to analyze concentration of the plating solution after supplying deionized water as well as bath solution.

The deionized water may be supplied at an amount calculated by subtracting a brought-out amount by the substrate and/or analysis consumption amount used for composition analysis from a total decrease amount of the plating solution.

The supply amount of the deionized water is inherently the amount corresponding to evaporation resulting from heating of the plating solution. However, various other factors influence the plating solution amount, and there is no method for directly measuring the evaporation amount. These other factors include brought-in solutions such as deionized water deposited on the substrate which was used for rinsing as a pretreatment, or deionized water used for rinsing the substrate in the plating vessel after plating. The brought-in solutions cancel the evaporated water and categorized as the total decrease of the plating solution. The amount of the brought-out plating solution and those consumed for solution analysis belongs to decrease of the plating solution itself, and if this is compensated by adding deionized water, the plating solution will be diluted. Therefore, these amounts should be excluded from the deionized water supply amount. Thus, the amount of deionized water supply is calculated by subtracting those from the total decrease.

The above described process is for compensating decrease of the plating solution based on routine plating operation, and decrease of the plating solution can occur due to other than routine plating operation. If the case includes such non-routine factors, the amount of supply of deionized water should be determined by subtracting those corresponding to the decrease due to the non-routine factors from the total decrease of the plating solution.

The bath solution may be supplied at an amount corresponding to a brought-out amount by the substrate and/or analysis consumption amount used for composition analysis.

The amount of the brought-out plating solution and those consumed for solution analysis belongs to decrease of the plating solution itself, and it is preferable to compensate for those losses with a bath solution containing all or major necessary effective components at prescribed concentrations for the concentration management purpose. It is possible to supply deionized water and one or more makeup solutions respectively containing only specific component. This method may require further concentration adjustment to thereby make the process complicate. When supplying the bath solution, amount can be calculated by summing an accumulated brought-out amount and an accumulated analyzer consumption. The accumulated brought-out amount is calculated by multiplying the average brought-out amount per one substrate with the number of processed substrates, and the accumulated analyzer consumption is calculated by multiplying the average analyzer consumption with the number of analyses. This calculation process can be computerized by establishing a suitable algorism.

The above described process for supplying and bath solution is for compensating decrease of the plating solution based on routine plating operation. If decrease of the plating solution occur due to other than routine plating operation such as exchange of filters, the amount corresponding to the decrease due to the non-routine factors should be added to the bath solution supply.

The makeup solution may be supplied by analyzing concentration of the effective component decreased through plating, at an amount necessary to recover a prescribed concentration. Analyzing methods for the effective components within the plating solution include: absorptiometry; titration; ion chromatograph; capillary electrophoresis, etc. A solution composition analyzer may be provided with the device using these methods and is supplied with a sampled plating solution necessary for analysis from a plating solution reservoir tank by a suction pump, for example to analyze those components. The analyzed results can be compared with the prescribed concentrations of the effective components, and a necessary quantity of the makeup solution(s) for recovering the prescribed concentrations is calculated if any of the components is in short.

The total decrease amount may be obtained by measuring decreased liquid level of the plating solution within the plating solution reservoir tank.

A regulation range for concentration of the electroless plating solution differs depending on the plating process, and generally, it is necessary to control variance within ±10%. When obtaining the total decrease of the plating solution by measuring a liquid level decrease, a level sensor can offer a ±0.5 mm precision. This makes possible to control the amount of the plating solution, depending on the size of the plating vessel, within ±0.5% for the plating vessel containing 100 L of plating solution. Thus, by measuring decrease of the surface level of a plating solution reservoir tank, concentration fluctuation due to water evaporation can be controlled within a prescribed range.

The brought-out amount may be calculated as a product of an average brought-out amount per a single substrate and the number of processed substrate.

The average brought out quantity of the plating solution can be determined by actually measuring the amount in a plating operation by introducing the actual plating solution in the plating apparatus. Supply of deionized water or bath solution can be controlled by inputting the average brought-out value obtained as above into an algorism, calculating the product of the number of the processed substrate after the last solution supply and the average brought-out value, and determining the supply amount by subtracting the calculated product from the total decrease of the plating solution.

The analysis consumption amount maybe calculated as a product of an average analysis consumption amount per a single analysis and the number of analyses after the last solution supply.

The necessary total amount for analyzing can be derived from a flow rate meter provided in a sampling line for flowing sample plating solution from the plating solution reservoir tank to the solution component analyzer, or a fixed value can be used. These are inputted into the calculation algorism. Calculated product of the inputted value and the number of analyses performed after the last solution supply is used for determining the deionized water supply amount by subtracting the result from the total decrease of the plating solution, or for determining the supply amount of the bath solution.

When supplying any of deionized water, bath solution, and makeup solution, solution may be supplied while the supply amount is limited to control variation of temperature or concentration of the plating solution within a prescribed range.

Generally, the electroless plating deposits films in a plating solution at a temperature higher than the room temperature. The deposition rate for the electroless plating is highly temperature dependent, so that it is necessary to control the plating solution temperature within a range for depositing films with good repeatability. If the deionized water, bath solution, or makeup solution at the room temperature are supplied to the plating solution, the solution temperature will temporarily be lowered. Thus, by restricting the total amount for those solutions supplied at one time, the temperature lowering is maintained within an allowable range. For example, when the plating solution temperature is 70° C. and the effective volume of the plating solution reservoir tank is 100 L, the temperature lowering is maintained within 1° C.

In an another aspect of the present invention, an apparatus for processing a substrate comprises; a preprocessing unit for preprocessing a surface of the substrate; an electroless plating unit for depositing a metal or alloy film on a surface of the substrate by an electroless plating process using a plating solution; a plating solution reservoir tank for reserving, supplying to the plating unit, and circulating between the plating unit, a component supply system for supplying at least three supply solutions consisting of a deionized water, a bath solution containing necessary components for plating, and a makeup solution containing at least one effective component necessary for plating; and a solution component analyzer for analyzing component in the plating solution.

The component supply system may comprise a control unit for individually controlling the at least three supply solutions.

The control unit may accumulate data for concentrations of the effective components within the plating bath or quantity of the plating solution as parameters relative to the number of processed substrates or operation time to calculate optimized supply amount for at least one of the deionized water, bath solution, or makeup solution.

For example, the deionized water supply amount can be optimized and controlled according to the following equation.

ΣVsupDIW=(Veva−Vwaf)

wherein, VsupDIW (mL) is the deionized water supply amount, Veva (mL) is an evaporated deionized water amount, and Vwaf (mL) is a diluted or added deionized water amount through rinsing or cleaning.

Each term on the right can be expressed as follows:

VeVa=Ueva×δt

Vwaf=Pwaf×Nwaf

wherein, Ueva (mL/min) is a evaporation amount per unit time depending on the bath temperature, δt is accumulated time since last time the deionized water is supplied, Pwaf (mL/str) is a total rinsing liquid (deionized water) supply per one substrate, and Nwaf is an accumulated number of substrates processed since the last time deionized water was supplied.

Also, the bath solution supply amount can be optimized and controlled according to the following equation.

ΣVMsup=(VMsam+VMwaf)

VMsam=ρMsam×Nsam

VMwaf=ρMwaf×Nwaf

wherein, ΣVMsup (mL) is the bath solution supply amount, VMsam (mL) is a total amount of plating solution consumed in the composition analyzer, VMwaf (mL) is a brought-out amount of plating solution from the system during plating, ρMsam (mL) is a consumption for one analysis in the solution composition analyzer, Nsam is the number of analysis since last time the solution adjustment was conducted, ρMwaf (mL) is a brought-out amount of plating solution per one substrate, and Nwaf is an accumulated number of substrates processed since last time the solution adjustment was conducted.

The controller unit may be installed with a program to which at least one data selected from a data group is inputted. The data group may include: a data of decreased amount of the plating solution within the plating solution reservoir tank; an analysis data of effective component concentration within the plating solution; a data of an average amount consumed for one analyzing process for determination of the effective component; a data of an average brought-out amount of the plating solution with one substrate; a data of the total number of the substrate processed or the number per unit time.

### BRIEF DESCRIPTION OF THE DRAWINGS

FIG. 1 is a cross-sectional view of a semiconductor substrate formed with a protective film;

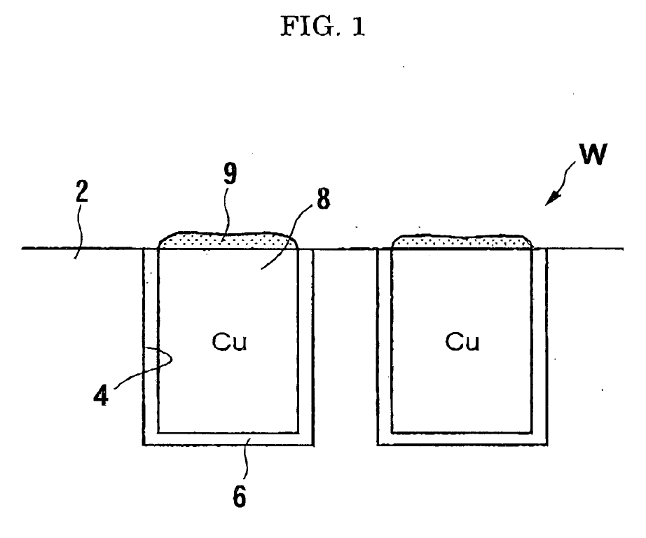

FIG. 2 is a plan view of a substrate processing apparatus according to an embodiment of the present invention;

FIG. 3 is a flow chart of the process according to an embodiment of the present invention;

FIG. 4 is a front view of a preprocess unit delivering a substrate;

FIG. 5 is a front view of a preprocess unit processing a substrate with a chemical agent;

FIG. 6 is a front view of a preprocess unit rinsing a substrate;

FIG. 7 is a cross-sectional view of a processing head during delivery of a substrate;

FIG. 8 is a partial enlarged view of FIG. 7;

FIG. 9 is a partial enlarged view of a processing head when fixing a substrate;

FIG. 10 shows a schematic diagram of the preprocess unit;

FIG. 11 is a cross-sectional view of a processing head during delivery of a substrate;

FIG. 12 is a partial enlarged view of FIG. 11;

FIG. 13 is a partial enlarged view of a processing head when fixing a substrate;

FIG. 14 is a partial enlarged view of a processing head when plating a substrate;

FIG. 15 is a cross-sectional view of a plating unit when plating vessel cover is closed;

FIG. 16 is a cross-sectional view of a plating unit when head portion of the substrate head is elevated above;

FIG. 17 shows a schematic diagram of the electroless plating unit;

FIG. 18 shows a schematic diagram of the electroless plating unit according to another embodiment of the present invention;

FIG. 19 shows a schematic diagram of a composition supply system of the electroless plating unit shown in FIG. 17;

FIG. 20 is a perspective view of a post-process unit and a dryer unit;

FIG. 21 is a plan view of a post-process unit; and

FIG. 22 is a plan view of a dryer unit.

### DETAILED DESCRIPTION OF THE PREFERRED EMBODIMENTS

The embodiments of the present invention will be explained with reference to the attached drawings. The following embodiment handles a process of selectively covering the exposed surface of an interconnect (metal layer) 8 or wiring with a protective film (capping member) 9 made of a Co—W—P alloy film to protect the interconnect 8.

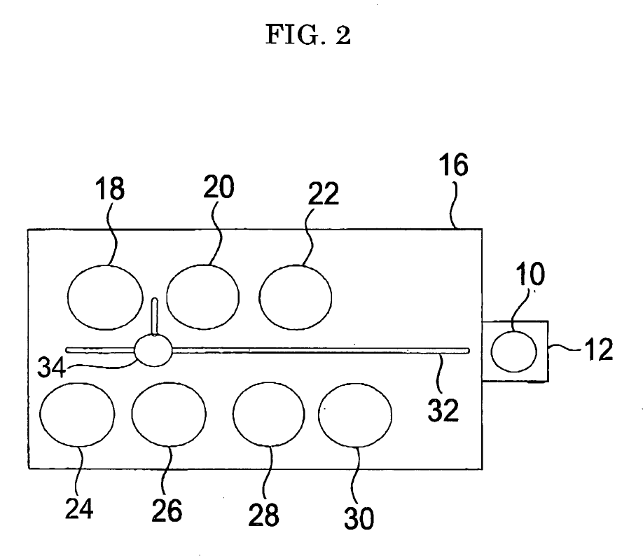

FIG. 2 shows a plan view of a substrate processing apparatus according to an embodiment of the present invention.

As shown in FIG. 2, the substrate processing apparatus comprises a load/unload unit 12 for loading substrate cassettes 10 containing therein substrates W on which interconnects 8 (matrix metal) made of copper etc. are formed within interconnect recesses 4 formed on the surface. A long a lateral edge of a rectangular housing 16 comprising an exhaustion system, a first preprocess unit 18 for cleaning the surface of the substrate W, a second preprocess unit 20 for activating the exposed surface of the cleaned interconnect by applying a catalyst, and an electroless plating unit 22 for electrolessly plating the surface of the wafer are arranged in series.

Along the other lateral edge of the housing 16, a post-process unit 24 for post-processing the substrates W for facilitating selectively forming the protection film 9 on the surface of the interconnects 8 through electroless plating process, a drying unit 26 for drying the substrate W after the post-process, a heat treatment unit 28 for annealing the substrate W after drying, and a film thickness measuring unit 30 for measuring the film thickness of the protective films 9 formed on the surface of the interconnects 8 are arranged in series. Also, a transfer robot 34 for delivering substrates W between each of these units and the cassettes 10 loaded on the load/unload unit 12 is provided between those linearly arranged units.

The housing 16 is shaded or shielded so that the following steps are performed in a shaded state in the housing 16 and the rays from illumination lights are not incident to the interconnect. Thus, corrosion of the interconnect surface due to photoelectric potential caused by the incident rays on the interconnects 8 can be prevented.

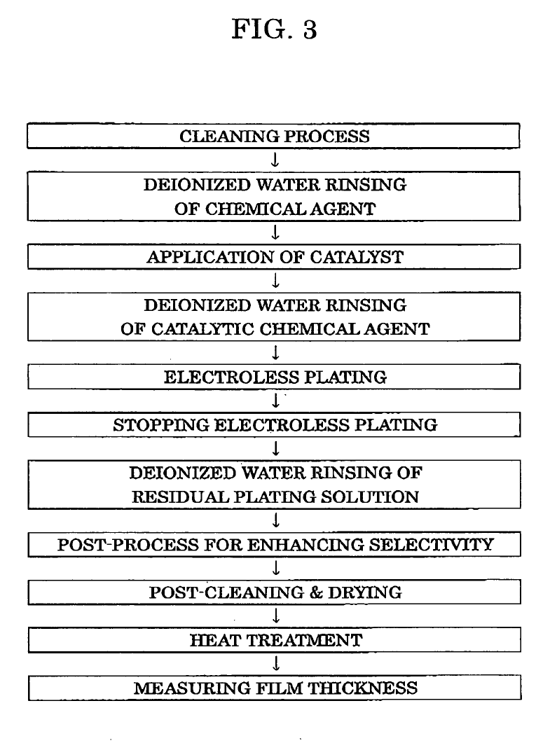

Next, electroless plating process using the above described substrate processing apparatus will be explained with reference to FIG. 3. The substrates W are loaded on a substrate cassette on the load/unload unit 12, after being formed with interconnects 8 and dried, with the surface facing upward. A transfer robot 34 takes one substrate W therefrom and delivers it to the first preprocess unit 18. In the first plating unit, the substrate W is held with the surface facing downward and subjected to cleaning using a chemical agent as a pretreatment for plating. For example, a chemical agent such as diluted H₂SO₄ at a temperature of 25° C. is spurted toward the surface of the substrate W for removing CMP residuals such as copper on the insulative film or oxides on the surface of the interconnects B, and rinsing away the cleaning agent remaining on the surface of the substrate W with a rinsing liquid such as deionized water.

Following chemicals can be used for the cleaning agent described above: an inorganic acid of pH not larger than 2 such as hydrofluoric acid, sulfuric acid, and hydrochloric acid; a chelatable acid of pH not larger than 5 such as formic acid, acetic acid, oxalic acid, tartaric acid, citric acid, maleic acid, and salicylic acid; or an acid of pH not larger than 5 and added with a chelating agent such as halide, carboxylic acid, dicarboxylic acid, hydroxy carboxylic acid, or their water soluble salt. By using the above exemplified chemicals, CMP residuals containing copper on an insulative film or oxides on the matrix or interconnect surface are removed to enhance plating selectivity or metal adhesion to the matrix. Anticorrosives used in CMP processes, which usually suppress deposition of plating films, can also be effectively removed by using an alkali agent capable of removing those anticorrosives such as tetramethylammonium hydroxide (TMAH). The above listed acids can be replaced by an alkali solution of amino acid such as glycine, cysteine, or methionine.

Further, rinsing the cleaned substrate surface with a rinsing liquid can prevent chemicals used for cleaning and remaining on the substrate surface from blocking the activation process to follow. Usually, deionized water is used as the rinsing liquid. However, depending on the material of the matrix to be plated, even when using deionized water, the interconnect material may suffer corrosion due to a local vessel effect. In that case, it is preferable to use a rinsing water, which is removed of impurities and has a high reducing ability such as a hydrogen gas dissolved deionized water, or electrolyzed cathodic water which can be obtained by electrolyzing deionized water in a diaphragm vessel. Since chemical agents for cleaning process may have some corrosiveness against interconnect material, it is preferable to shorten the time between cleaning and rinsing as much as possible.

Next, the substrate W after cleaning and rinsing is transferred to the second preprocess unit 20 with the transfer robot 34, in which the substrate W is supported with the surface facing downward to be applied with a catalyst. This is performed by spurting, for example, a mixed solution of PdCl₂ and HCl held at a temperature of 25° C. toward the surface of the substrate W to apply Pd as a catalyst on the surface of the interconnect. This process forms Pd nuclei as seeds and activates the exposed surface of the interconnect. Thereafter, the substrate surface is rinsed to remove residual catalyst chemical with a rinsing liquid such as deionized water.

As the catalyst chemical agent, inorganic or organic acid solutions containing Pd are used. If Pd concentration within the catalyst chemical solution is too lean, plating does not occur due to a low catalyst density on the matrix surface to be plated, and if concentration is too dense, defects such pitching may occur on the interconnect.

In order to deposit uniform and continuous electroless plating films on the whole surface of the substrate W, a certain amount of catalyst application on the matrix surface is required, and when using palladium as a catalyst. It has been experimentally recognized that more than 0.4 μg of palladium application per 1 cm² of the matrix surface is adequate for that purpose. It is also known that excessive amount of Pd application facilitates erosion of the matrix and raises the total resistance for the plated layer and matrix. It has been experimentally recognized that more than 8 μg palladium application per 1 cm² of matrix surface makes this tendency remarkable.

By applying a catalyst on the surface of the substrate W, selectivity for electroless plating can be enhanced. Among various kinds of catalytic metals, Pd is most preferable because of an easy control of reaction rate etc. Application of catalyst can be performed by various methods which are categorized in immersing the whole substrate W in a catalyst solution and spraying it on the substrate surface. Any of these methods can be selected according to the composition of the film to be plated or thickness of the film. Spray method is generally superior due to its high repeatability for thin film deposition.

In order to enhance selectivity, it is necessary to remove residual Pd from the surfaces of the interlayer insulative film or interconnect, and for that purpose, deionized water rinsing is generally used. Since residual catalyst solutions may cause corrosion of interconnect material or interfere with the following plating process, shorter time between catalyst application and rinsing is preferable. As for the rinsing liquid, deionized water, hydrogen gas dissolved water, electrolyzed cathodic water can be used similarly to the cleaning process. A plating solution for next electroless plating process can also be used for providing a time to familiarize the substrate W with the plating solution. The above catalyst application process for enhancing selectivity is not necessary when using alkylamineborane such as dimethylamineborane as a reducing agent.

The substrate W applied with the catalyst and rinsed is transferred to an electroless plating unit 22 with a transfer robot 34, in which the substrate W is held with the surface facing downward and electrolessly plated. This is performed by, for example, immersing the substrate W into a Co—W—P plating solution of a temperature 80° C. for about 120 seconds to electrolessly plate a Co—W—P protective film (capping film) 9 selectively on an activated interconnect surface. An exemplified prescription of the plating solution is as follows.

CoSO₄.7H₂O: 14 g/L

Na₃C₆H₅O₇.H₂O: 70 g/L

H₃BO₃: 40 g/L

Na₂WO₄.2H₂O; 12 g/L

NaH₂PO₂.H₂O: 21 g/L

pH: 9.5

It is preferable to maintain the depositing rate of the protective film 9 10˜600 Å per minute, and preferably 10˜200 Å per minute. The deposition rate directly governs the production rate so that an excessively small deposition rate is not acceptable, while an excessively large production rate cannot provide uniform protective films 9 with a good repeatability. The protective film thickness is required to be at least 50 Å thick for establishing its object and also requires to be less than 500 Å for restricting interconnect resistance raise to a minimum. A suitable deposition rate is 10˜600 Å per minute in general, 10˜200 Å per minute preferably, and 20˜100 Å more preferably.

If a large variance of thickness exists for the plated protective films 9 on different substrates W, a large variance also exists in performance of the obtained protective films 9 or electrical resistance of the interconnects 8, and process margins in the manufacturing steps to follow will be narrow. Therefore, it preferable to restrict variance of thickness of the plated protective films 9 on different substrates W within ±10%, and more preferably, within ±5%. Control of the deposition rate and variance thereof in depositing the protective film is managed as follows.

To start with, the temperature of the plating solution is controlled so that the temperature of the substrate W during plating is controlled in a range 70˜90° C. and variance of the solution temperature is controlled within ±2° C. in general, and preferably ±1° C.

Among various kinds of electroless plating solutions for depositing protective films 9 on the interconnect surface, every one of them requires heating, so that plating solutions of less than 70° C. cannot provide adequate deposition rate. However, plating solutions of more than 90° C. cannot provide a stable deposition process due to an excessively high water evaporation as well as excessively high deposition rate. Therefore controlling the solution temperature between 70° C. and 90° C. can provide stable and highly repeatable deposition process with 10˜200 Å deposition rate per minute.

Also, deposition rate of the protective film in an electroless plating process depends largely on the plating solution temperature and small temperature difference influences largely to the deposition rate. Therefore controlling the temperature variance within ±2° C. and more preferably ±1° C. can also control the deposition rate among the substrates W ±10% generally, and ±5% preferably.

As for water quantity within the plating solution, it is preferable to control plating solution decrease due to water evaporation within ±10% relative to the initial amount. In order to manage the solution quantity control, it is preferable to replenish deionized water to compensate loss of the solution by measuring the solution surface level within the plating solution reservoir tank.

As described above, temperature of the plating solution for electrolessly plating metal or alloy films is as high as 70° C. so that a considerable amount of water evaporates from the plating solution. This is not negligible for controlling the plating solution composition as well as deposition rate within a certain range to limit the film thickness variance within a certain range. Therefore, it is preferable to control the decreased amount of the plating solution due to evaporation within ±10% relative to the initial amount and more preferably within 15%. Thus, by measuring the water level within the plating solution reservoir tank and supplying decreased amount with deionized water to maintain the water ratio in the plating solution constant.

The concentration of metal ions within the plating solution such as Co ions or Ni ions should be controlled within the level of 0.01˜0.1 mol/L and variance of concentration is controlled within 120%. When applying Co or Ni alloy film as the protective film, a plating solution containing Co ions or Ni ions is used and the deposition rate depends on the metal ion concentration to a certain extent. Thus, by controlling the metal ion concentration within the electroless plating solution not less than 0.01 mol/L and not more than 0.1 mol/L, the deposition rate can be controlled 10˜200 Å per minute and the deposition is performed with a good repeatability.

The deposition rate for the protective film during the electroless plating process does not depend on the metal ion concentration in the plating solution so much when compared to the plating solution temperature. Thus, by controlling variance of Co or Ni ion concentration within ±20% generally, and ±10% preferably, the deposition rate variance among different substrates w can be controlled within ±10% generally, and ±5% preferably. By measuring the Co or Ni ion concentration within the plating solution by an absorptiometry analyzer, anion chromatograph analyzer, a capillary electrophoresis analyzer, or a chelatometric titration analyzer, and replenishing solutions containing these metal ions to supply necessary metal ions based on the measurement, metal ion concentration within the plating solution can be controlled within a certain range.

When applying an alloy film containing W as the protective film 9, a plating solution containing tungstic acid ions and/or tungsten phosphoric acid ions may be used. In this case, concentration of tungstic acid ions and/or tungsten phosphoric acid ions should be controlled within a range of 1.5-30.0 g/L as converted to tungsten, and the concentration variance should be controlled within ±40%.

When applying an alloy film containing W as the protective film, a plating solution containing tungstic acid ions and/or tungsten phosphoric acid ions is used and the deposition rate depends on the metal ion concentration to a certain extent. A certain amount of W concentration within the protective film is necessary for performing a protective function. Thus, it is necessary to control the tungstic acid ion and/or tungsten phosphoric acid ion concentration within the electroless plating solution not less than 1.5 g/L and not more than 30 g/L as converted to tungsten to control the deposition rate 10˜200 Å per minute and deposit the film with a good repeatability.

As described above, the deposition rate for the protective film during the electroless plating process does not depend on the ion concentration converted to tungsten concentration in the plating solution so much when compared to the Co or Ni ion concentration. Thus, by controlling variance of the ion concentration converted as W concentration within ±40% generally, and ±20% preferably, the deposition rate variance among different substrates W can be controlled within ±10% generally, and ±5% preferably.

By measuring the ion concentration converted as w concentration within the plating solution by a capillary electrophoresis analyzer, or from Co ion or Ni ion consumption, and replenishing solutions containing tungstic acid ions and/or tungsten phosphoric acid ions to supply necessary metal ions based on the measurement, metal ion concentration within the plating solution can be controlled within a certain range.

When using a plating solution containing hypophosphorous acid ions and/or alkylamineborane such as dimethylamineborane as a reducing agent, the hypophosphorous acid ion, alkylamineborane, and/or NaBH₄ concentration within the electroless plating solution is controlled 0.05˜0.3 mol/L, and variance is controlled within ±40%.

When applying an alloy film containing Co and Ni as the protective film, a plating solution containing hypophosphorous acid ions and/or alkylamineborane as a reducing agent is generally used. More than a certain amount of these reducing agents does not affect the deposition rate, and excessive amount of concentration extensively decreases W concentration within the deposited protective film to negate its protective function. Thus, it is preferable to control the hypophosphorous acid ion, alkylamineborane, and/or NaBH₄ concentration within the electroless plating solution not less than 0.05 mol/L and not more than 0.3 mol/L to control the deposition rate 10˜200 Å per minute and deposit the film with a good repeatability.

As described above, dependency of the deposition rate for the protective film during the electroless plating process on the reducing agent concentration in the plating solution is relatively small. Thus, by controlling variance of the hypophosphorous acid ion, alkylamineborane, and/or NaBH₄ concentration within ±40% generally, and ±20% preferably, the deposition rate variance among different substrates W can be controlled within ±10% generally, and ±5% preferably.

By measuring the hypophosphorous acid ion, alkylamineborane, and/or NaBH₄ concentration within the plating solution by an oxidation-reduction titration analyzer or a capillary electrophoresis analyzer, and replenishing solutions containing hypophosphorous acid ions and/or alkylamineborane to supply necessary hypophosphorous acid ions and/or alkylamineborane based on the measurement, the concentration within the plating solution can be controlled within a certain range.

When using a plating solution containing a chelating agent, the chelating agent concentration within the electroless plating solution is controlled 0.05˜0.5 mol/L, and variance is controlled within ±30%.

When applying an alloy film containing Co and Ni as the protective film, a plating solution containing a chelating agent is generally used and the deposition rate depends on the chelating agent concentration to a certain extent. Thus, it is preferable to control the chelating agent concentration within the electroless plating solution not less than 0.05 mol/L and not more than 0.5 mol/L to control the deposition rate 10˜200 Å per minute and deposit the film with a good repeatability.

Dependency of the deposition rate for the protective film during the electroless plating process on the chelating agent concentration in the plating solution is relatively small similarly to W or Mo ion concentration. Thus, by controlling variance of the chelating agent concentration within ±30% generally, and ±15% preferably, the deposition rate variance among different substrates W can be controlled within ±10% generally, and ±5% preferably.

By measuring the chelating agent concentration within the plating solution by a chelatometric titration analyzer or a capillary electrophoresis analyzer, and replenishing solutions containing chelating agent to supply necessary chelating agent based on the measurement, the chelating agent concentration within the plating solution can be controlled within a certain range.

When using a plating solution containing a pH buffer and an alkaline agent, pH of the electroless plating solution is set 8˜10, and variance is controlled within ±0.2. When applying an alloy film containing co and Ni as the protective film, a plating solution containing a pH buffer and an alkaline agent is generally used and the deposition rate is likely to largely depend on the pH value. Thus, it is necessary to control pH of the electroless plating solution 8˜10 generally, and 8.5˜200 Å preferably, to control the deposition rate 10˜200 Å per minute and deposit the film with a good repeatability.

Dependency of the deposition rate for the protective film during the electroless plating process on pH in the plating solution is large so that it is necessary to control variance of pH of the electroless plating solution within ±generally, and ±0.05 preferably, to control the deposition rate variance among different substrates W within ±10% generally, and ±5% preferably. By measuring pH of the plating solution by an electrode method or neutralization titration, and replenishing solutions containing pH regulator to correct pH fluctuation based on the measurement, pH of the plating solution can be controlled within a certain range.

It is preferable to measure the deposition rate of the protective film while electrolessly plating the film, which allows to confirm the actual deposition rate is in conformity with the predetermined value. This measurement process can be performed by immersing a quartz resonator in the plating bath, whose oscillation frequency attenuates as electroless plating film deposits on the quartz resonator.

The protective films 9 are generally very thin as describe above, and narrow control of the film thickness variance requires a method for measuring the deposition rate with a high sensitivity and high precision. By immersing the quartz resonator within the plating bath, these requirements can be fulfilled.

It is preferable to adjust plating time based on the measurement results of the deposition rate of the protective film. By increasing or decreasing the process time when the measured thickness differs from the anticipated, for example, this process enables to form a plating film of a predetermined thickness with a good repeatability.

The protective film can be suitably formed with a ternary alloy comprising Co, W, and P. This ternary alloy is advantageous for forming a thin film because it provides relatively small deposition rate among Ni-based alloys or Co-based alloys.

It is also advantageous that, when the plating film is formed by the ternary alloy, the average composition of the plating film is within the range of, Co: 75˜90 atm %; W: 1˜10 atm %; and P: 5˜25 atm %. In the composition of the ternary alloy containing Co, W, and P, percentage contents of W and P are in a trade-off relationship, and the deposition rate extremely lowers when the W content increases. At least 1 atm % of W is necessary for establishing protective function, and the upper limit of W should be 10 atm % in consideration of the deposition rate, and accordingly, the P content is 5˜25 atm %, and the Co content is 75˜90 atm %.

After withdrawing the substrate W from the plating bath, the surface of the substrate W is made to contact with a stopping solution comprising a neutral liquid of a pH of 6˜7.5 so as to stop the electroless plating process. By doing so, the plating reaction on the substrate W is rapidly stopped soon after withdrawing the substrate W to prevent unevenness from occurring within the plated film. The process time for this process is preferably 1˜5 seconds. As for the stopping solution, a deionized water, a hydrogen dissolved water, or an electrolyzed cathodic water can be used. The interconnect material may be corroded depending on the surface material composition of the substrate W, as described above, due to a local vessel effect. In this case, a deionized water added with reducibility is suitably used to avoid the above described disadvantage.

Then, the substrate W is rinsed with a rinsing liquid such as deionized water to remove the residual plating solution, and a process is finished for forming a protective film comprising a Co—W—P alloy film selectively on the interconnect surface for protecting the surface of interconnects 8.

Next, the substrate W after electroless plating is transferred to a post-process unit with the transfer robot 34 and is subjected to a post process treatment for enhancing selectivity of the protective film to raise yield of the product. This process is performed by supplying a chemical agent containing at least one of a surfactant, an organic alkali, and a chelating agent, while applying a physical force by a roller scrub cleaning process or a pencil cleaning process, on the surface of the substrate W to thereby perfectly remove plating residuals such as metal particles on the inter layer insulative film to enhance a selectivity of plating. By using these chemical agents, selectivity of electroless plating is enhanced efficiently. As for the surfactant, non-ionic detergent may be used, as for the organic alkali, 4th grade ammonium or amines may be used, and as for the chelating agent, ethylene diamine may be preferably used.

After using a chemical agent, the agent remaining on the substrate surface is rinsed away with a rinsing liquid. The rinsing liquid may be a hydrogen gas dissolved water or an electrolyzed cathodic water. By using deionized water having reducibility can prevent the interconnect material from being corroded due to a local galvanic vessel effect.

It is also possible to remove residuals on the inter layer insulative films by cleaning with a complexing agent, uniform etch back using etching solution, other than the physical cleaning process such as roller scrub cleaning or pencil cleaning, or any combination of the above methods to completely remove the residuals. The substrate W after the post process treatment is transferred to the drying unit 26 with the transfer robot 34, rinsed as is necessary, and rotated at a high speed to be spin-dried.

These sequential processes for electrolessly plating the plating film on the exposed surface of the interconnect are continuously performed and concluded with a drying process for finishing the substrate W into a dry state. Therefore, the substrate W can be transferred to the next processing stage as it is, and deterioration of the protective film is prevented while it is forwarded to the next stage.

While the substrate W is spin dried, it is preferable to control humidity of the atmosphere surrounding the substrate W by using dry air or inert gases. If the substrate W is dried in a usual atmosphere, water on the substrate W is scattered into the surrounding atmosphere to raise the humidity so that the substrate W after drying process still carries a large quantity of water which may cause another problem such as oxidation of the interconnect. It also may create a problem of water mark generation due to recapturing of the mist within the spin drier. By controlling humidity within the atmosphere by supplying dry air or dry nitrogen gas, the above mentioned defects can be avoided.

The substrate W after spin-drying is transferred to a heat treatment unit 28 with transfer robot 34 to anneal the substrate W after the post process treatment for refining the protective film. Annealing temperature necessary for refining the protective film is equal to or more than 120° C. by considering a practical annealing process time, and not more than 450° C. when considering the heat resistance of the material constructing the semiconductor device on the substrate surface. Thus, the heat treatment temperature should be 120˜450° C., for example. By heat-treating the substrate W, barriering function of the protective film as well as its bond-tightness to the interconnect can be enhanced.

Then, the substrate W after the heat treatment is transferred to the film thickness measuring unit 30, which may be of an optical type, AFM, or EDX with the transfer robot 34 for measuring the thickness of the protective film. The substrate W is then returned to a substrate cassette loaded on the load/unload unit 12 with the transfer robot 34.

Thickness of the protective film measured by an on-line or off-line process is fed back the controller to adjust the processing time for plating the next substrate in accordance with the measured result. This process can provide protective film with a constant thickness as a result of controlled processing time.

When forming the protective film on the exposed surface of the interconnects 8, it is preferable to planarize the exposed surface of the interconnects 8 by using one of chemical polishing, electrical chemical polishing, and composite electrical chemical polishing so as to provide a more planarized protective film.

Next, each unit equipped to the substrate processing apparatus shown in FIG. 2 will be described in detail. The first preprocess unit 18 and second preprocess unit 20 have the same structure but are operated with different processing solution (chemical agent) utilizing a liquid separation system for preventing different liquids from mixing each other. In these units, the substrate W is transferred with the surface facing downward, and the periphery of the lower surface, which is to be processed, is sealed and fixed by pressurized on the rear surface.

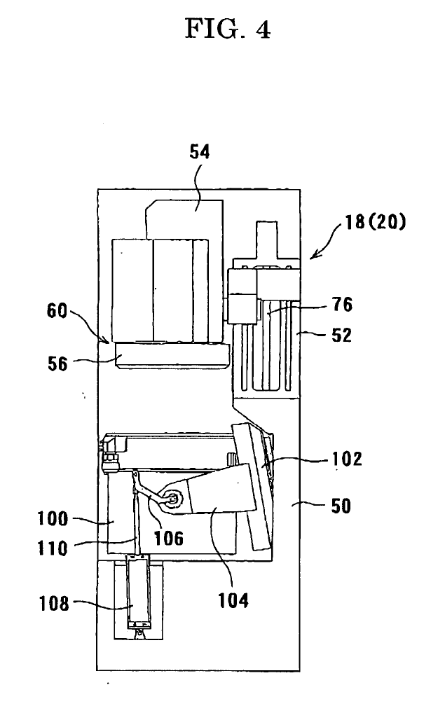

These processing units 18, 20 respectively comprise, as shown in FIGS. 4 to 7, a fixed frame 52 attached to the upper area of a base frame 50 and a movable frame 54 vertically movable relative to the fixed frame 52. A processing head 60 is supported by the movable frame 54 by being suspended therefrom. The processing head 60 comprises a flat cylindrical housing portion 56 opening to the bottom and a substrate holder 58. A servo motor 62 for driving the processing head 60 is provided on the movable frame 54 and has a hollow drive shaft 64 extending downward, and the housing portion 56 of the processing head 60 is connected to the lower end of the drive shaft 64.

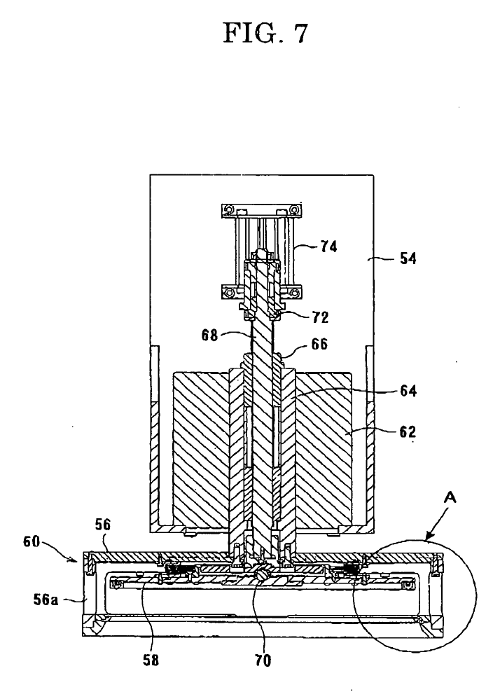

Inside the drive shaft 64, as shown in FIG. 7, a vertical shaft 68 is inserted to rotate integrally with the drive shaft 64 via a spline 66. And the vertical shaft 68 has a lower end connected to the substrate holder 5B of the processing head 60 via a ball joint 70. The substrate holder 58 is located within the housing portion 56. The upper end of the vertical shaft 68 is connected to a fixing ring elevation cylinder 74, which is fixed to the movable frame 54, via a bearing 72 and a bracket. Thus, the vertical shaft 68 is movable by being driven by the elevation cylinder, independent of the drive shaft 64.

A vertically extending linear guide is attached to the fixed frame 52 for guiding the vertical movement of the movable frame 54, so that the movable frame 54 is vertically moved by the activation of the head elevation cylinder (not shown) along with the linear guide 76.

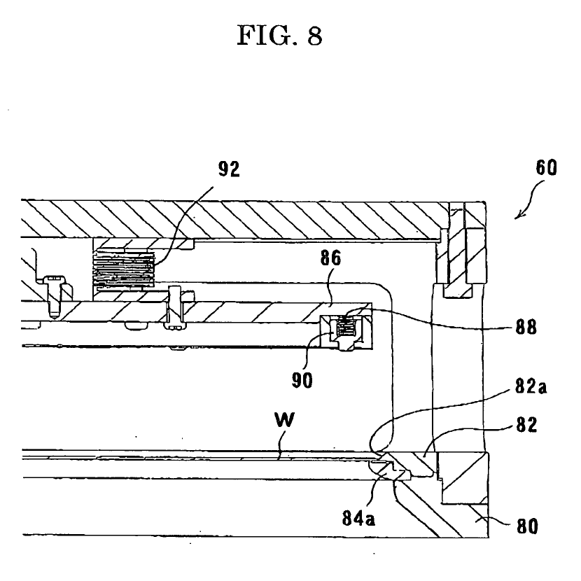

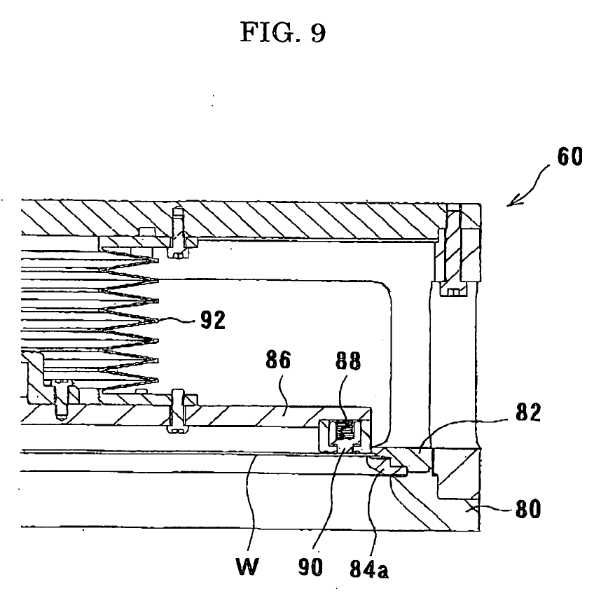

A substrate inserting window 56a is provided on the circumferential wall of the housing portion 56 of the processing head 60 for inserting the substrate to the inside of the housing portion 56. A seal ring 84a is provided at the lower portion of the housing portion 56 of the processing head 60, as shown in FIGS. 8 and 9, which is cramped at its periphery by a main frame 80 made of PEEK, for example, and a guide frame 82. The seal ring 84a is provided for contacting with the periphery of the lower surface of the substrate W to seal there.

At the periphery of the lower surface of the substrate holder 58, a substrate fixing ring 86 is secured, and a spring member 88 is arranged within the substrate fixing ring 86 so that a cylindrical pusher member 90 is projecting from the lower surface of the substrate fixing ring 86 by the elastic force of the spring member 88. A flexible cylindrical bellows plate 92 made of Teflon (trade name), for example is provided for sealing the interior air tightly between the upper surface of the substrate holder 58 and the upper wall portion of the housing portion 56.

With such construction, while the substrate holder 58 is elevated, the substrate W is inserted inside the housing portion 56 through the substrate inserting window 56a. Subsequently, the substrate W is guided by a tapered inner circumferential surface 82a of the guide frame 82 and is aligned and placed at a predetermined position on the upper surface of the seal ring 84a. At this stage, the substrate holder 58 is lowered to make the pusher member 90 of the substrate fixing ring 86 contact with the upper surface of the substrate W. By further lowering the substrate holder 56, the substrate W is pressed downward by the elastic force of the spring member 88. Thus, the periphery of the lower surface of the substrate W is in a pressured contact with the seal ring 84a so that the substrate W is held between the housing portion 56 and the substrate holder 58 while central region of the lower surface of the substrate W is sealed.

When the head rotation servo motor 62 is activated while the substrate W is held by the substrate holder 58, the drive shaft 64 of the motor and the vertical shaft 68 inserted inside the drive shaft 64 integrally rotate via a spline 66 for thereby rotating the housing portion 56 and substrate holder 58 together.

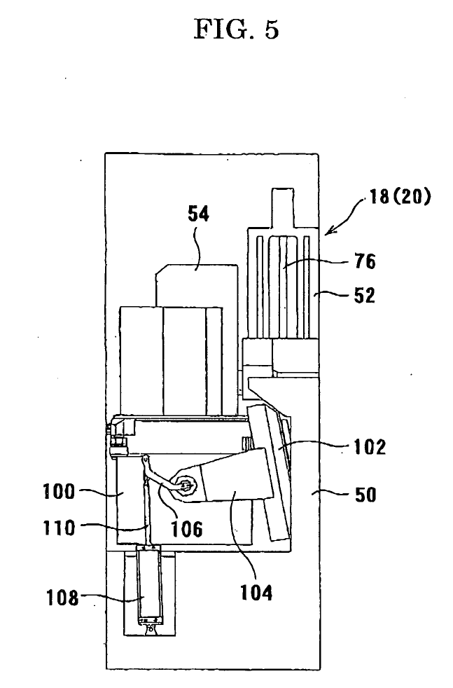

Beneath the processing head 60, a processing vessel 100 comprising an outer vessel 100a and an inner vessel 100b, which have an inner diameter slightly larger than the outer diameter of the processing head 60 and opening upward is provided. At the outer periphery of the processing vessel 100, a pair of legs 104 attached to a lid 102 are rotatably supported. A crank 106 is integrally connected to the leg 104 and the free end of the crank 106 is rotatably connected to a rod 110 of a lid drive cylinder 108, as shown in FIGS. 4 and 5. Thus, the lid 102 is moved by the lid drive cylinder 108 between a processing position covering the upper opening of the processing vessel 100 and a lateral withdrawal position on the upper surface of the lid 102, a nozzle plate 112 having a plurality of spurting nozzles 112a is provided for spurting electrolyzed ionic water having reducing ability, for example, toward outside or upward as described below.

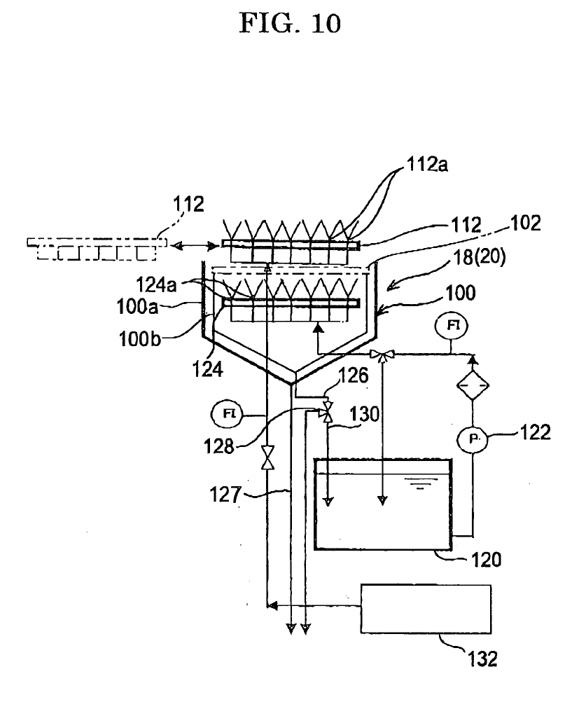

As shown in FIG. 10, a nozzle plate 124 comprising a plurality of spurting nozzles 124a is provided inside the inner vessel 100b of the processing vessel 100 for spurting upward a chemical agent supplied by a chemical agent pump 122 from a chemical agent tank 120. The spurting nozzles 124a are uniformly distributed over the whole cross section of the inner vessel 100b. A drain pipe 126 for draining out the chemical agent is provided at the bottom of the inner vessel 100b. In the midway of the drain pipe 126, a three way valve 138 is provided. One exit port of the three way valve 138 is connected to a return pipe 130, so that the drained chemical agent can be returned to the chemical tank 120 to reuse it if necessary.

In the embodiment, the nozzle plate 124 provided on the upper surface of the lid 102 is connected to a rinsing liquid source for supplying a rinsing liquid such as deionized water. Also, a drain pipe 127 is connected to the bottom of the outer vessel 100a.

By such construction, the processing head 60 is lowered to cover or block the upper opening of the processing vessel 100, and the spurting nozzles 124a provided on the nozzle plate 124 located inside the inner vessel 100b of the processing vessel 100 spurt a chemical agent toward the substrate W to uniformly supply the chemical agent on the whole area of the lower surface of the substrate W. The chemical agent is prevented from being scattered out of the processing vessel 100 and drained from the drain pipe 126 to the exterior Then the processing head 60 is elevated, and while the lid 102 closes and blocks the upper opening of the processing vessel 100, the rinsing liquid is spurted from the spurting nozzles 124a provided on the nozzle plate 124 arranged on the upper surface of the lid 102 toward the substrate W held by the processing head 60, so that a chemical agent remaining on the substrate surface is rinsed away and the rinsing liquid is flown through a space between the outer vessel 10a and inner vessel 100b and is drained through the drain pipe 126 to prevent it from flowing into the inner vessel 100b to be mixed with the chemical agent.

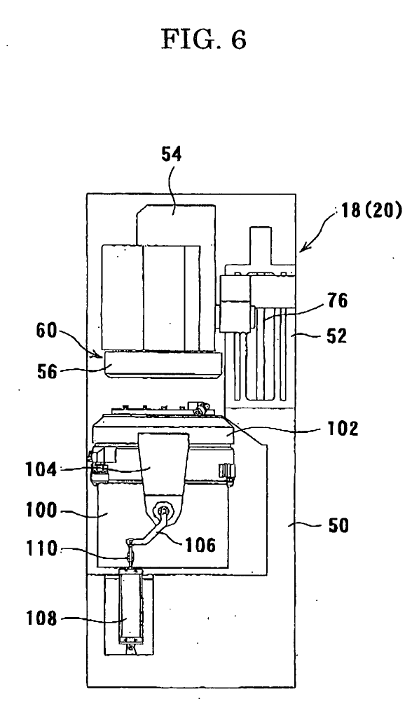

According to the preprocess unit, the substrate W is inserted inside the processing head 60 while the processing head 60 is elevated, as shown in FIG. 5, and then, the substrate processing head 60 is lowered until it covers the upper opening of processing vessel 100. While the processing head 60 is rotated to rotate the substrate w held by the processing head 60, the chemical agent is spurted toward the substrate w from the spurting nozzles 124a of the nozzle plate 124 located in the processing vessel 100, to uniformly spurt the chemical agent on the whole surface of the substrate W. The processing head 60 is elevated to a halt at a predetermined position, and the lid 102 at the withdrawal position is moved to a position to cover upper opening of the processing vessel 100, as shown in FIG. 6. At this state, the rinsing liquid is spurted from the spurting nozzles 112a of the nozzle plate 112 located on the upper surface of the lid 102 toward the rotating substrate W held by the processing head 60. Thus, processing of the substrate W with the chemical agent and rinsing of the substrate W with the rinsing liquid can be performed without mixing this two liquids.

By changing a lowered position of the processing head 60, a distance between the substrate W and the nozzle plate 124 can be adjusted so that the area where the chemical agent is spurted on the substrate W or a spurting pressure can be arbitrarily adjustable. When using a chemical agent while circulating it, effective components decrease as the process proceeds and the preprocess solution (chemical agent) is brought out by being carried by the substrate W. Thus, it is desirable to provide a preprocess solution regulation unit (not shown) for analyzing the composition of the preprocess solution and replenishing the chemical agent to compensate the shortage. Since usual cleaning chemicals comprise acid or alkali, it is possible to calculate shortage amount by measuring pH of the solution for supplying the component in short, as well as to supply decreased amount by monitoring the liquid level within the chemical agent tank 120. As for a catalyst solution such as acid Pd solution, the acid concentration can be calculated by measuring pH and the Pd concentration can be measured by a filtration or nephelometry method and decreased amount can be replenished in the same manner.

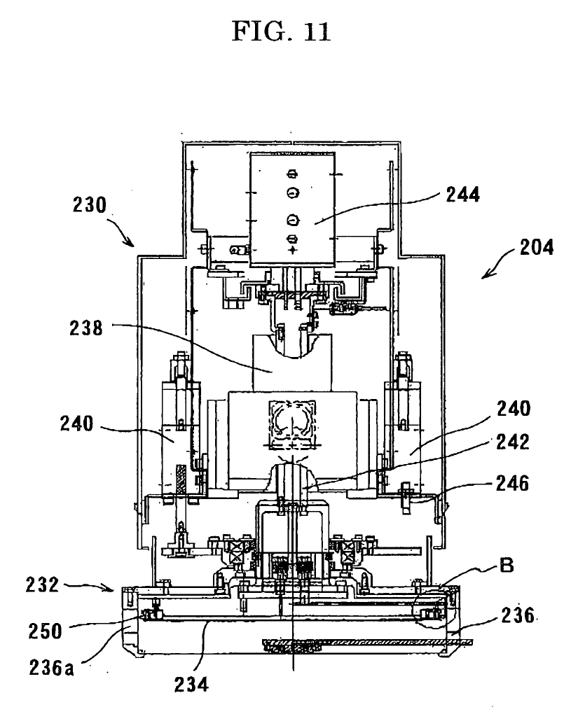

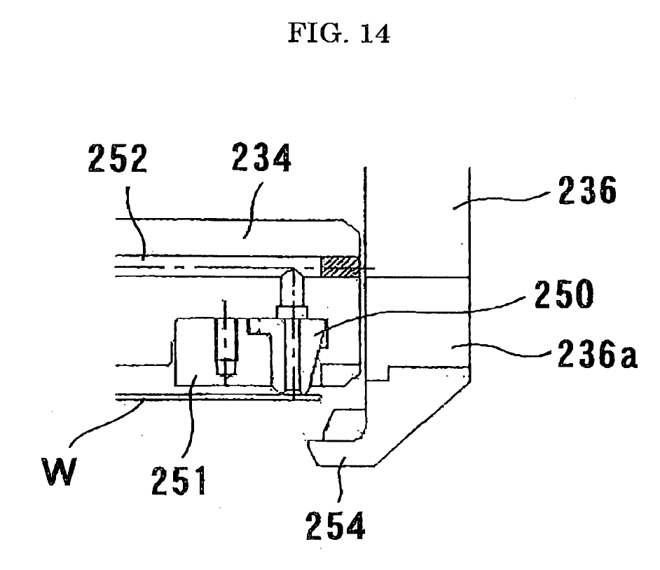

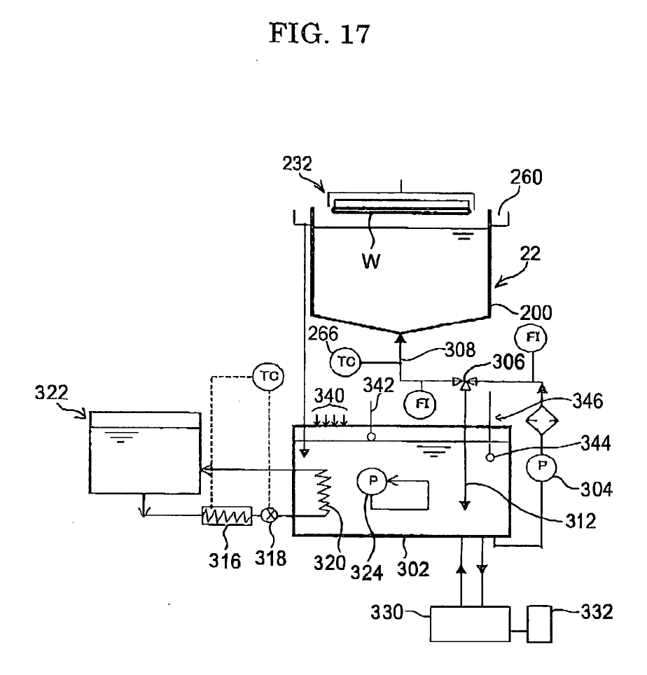

The electroless plating unit 22 is shown in FIGS. 11 through 17 in detail. The electroless plating unit 22 comprises a plating vessel 200 (shown in FIG. 17) and a substrate head 204 arranged above the plating vessel 200 for detachably supporting the substrate W.

The substrate head 204 comprises, as shown in FIG. 11 in detail, a housing portion 230 and a head portion 232. The head portion 232 is mainly comprised of a suction head 234 and a substrate support 236 surrounding the suction head 234. Within the housing portion 230, a substrate rotation motor 238 and a substrate support drive cylinder 240 are housed. The upper end of the hollow drive shaft 242 of the substrate rotation motor 238 is connected to a rotary joint 244, and the lower end of the drive shaft 242 is connected to the suction head 234 of the head portion 232. A rod of the substrate support drive cylinder 240 is connected to the substrate support 236 of the head portion 232. Inside the housing portion 230, a stopper 246 is provided for mechanically limiting the upward movement of the substrate support 236.

Between the suction head 234 and the substrate support 236, a similar spline structure is provided, so that the substrate support 236 and the suction head 234 are relatively movable along a vertical direction, and when the substrate rotation motor 238 is activated, the drive shaft 242 rotates the suction head 234 and substrate support 236 integrally.

To the periphery of the lower surface of the suction head 234, a suction ring 250 for mounting the substrate W on the lower sealing surface thereof with a suction force is attached via a fixing ring 251. A recessed portion 250a is continuously formed on the lower surface of the suction ring 250 along a circumferential direction, which is mutually communicated with a vacuum line 252 extending through the suction head 234 via a communication hole formed on the suction ring 250. Thus, the space within the recessed portion 250a is vacuumed to hold the substrate W with a suction force. Since the recessed portion 250a has a circular shape of a small radial width, the suction force to hold the substrate W causes minimal distortion of the substrate W. Also, by holding the substrate w with the suction ring 250 and dipping it into the plating solution, the whole circumferential area of the substrate W including the edge can be immersed into the plating solution. When releasing the substrate W from the suction head 234, N₂ gas is supplied through the vacuum line 252.

The substrate support 236 is formed in a hollow cylinder having a closed top end and an open bottom end, and has a circumferential wall formed with a substrate inserting window 236a for inserting a substrate W therethrough. At the lower end of the substrate support 236, an annular plate-like claw 254 is provided to protrude inward. Above the claw 254, a projection piece 256 having a tapered inner surface 256a is provided for guiding the substrate W.

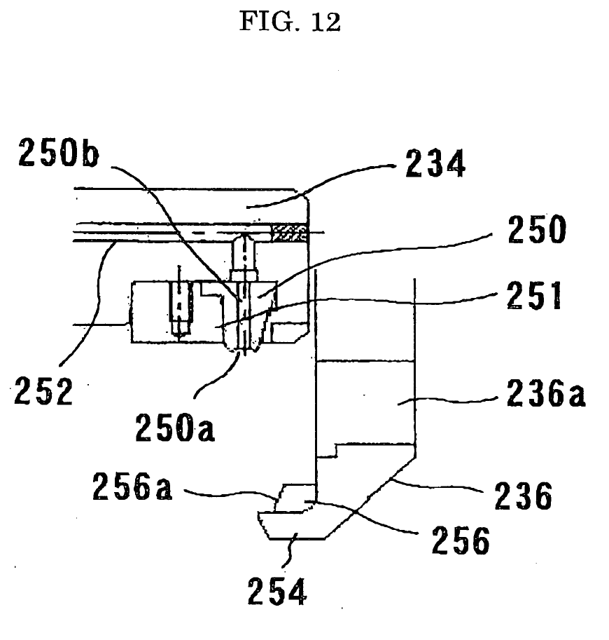

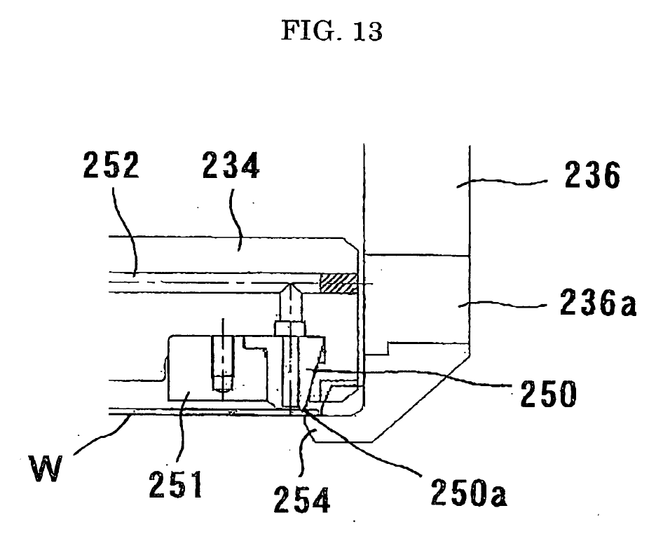

As shown in FIG. 12, the substrate support 236 is lowered and the substrate W is inserted from the substrate inserting window 236a. Then, the substrate W is guided by the tapered inner surface 256a of the projection piece 256 to be aligned and is placed on the upper surface of the claw 254. At this state, the substrate support 236 is elevated as shown in FIG. 13 so that the upper surface of the substrate W held on the claw 254 is made to contact with the suction ring 250 of the suction head 234. Next, the recessed portion 250a of the suction ring 250 is vacuumed through the vacuum line 252 and the substrate W is supported at the lower surface of the suction ring 250 by the suction force in a sealed manner at the periphery. When the substrate W is plated, the substrate support 236 is lowered by several millimeters to disengage from the substrate W to leave the substrate W to be held only by the suction ring 250. This process prevents the claw 254 from covering the periphery of the lower surface of the substrate W to interfere plating of the area.

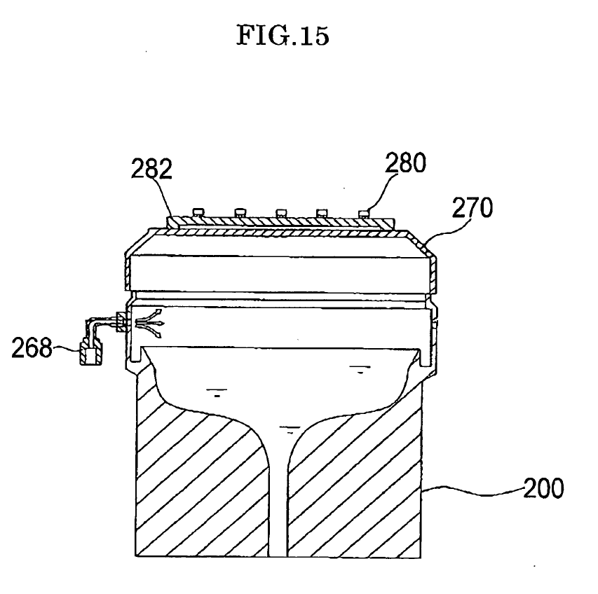

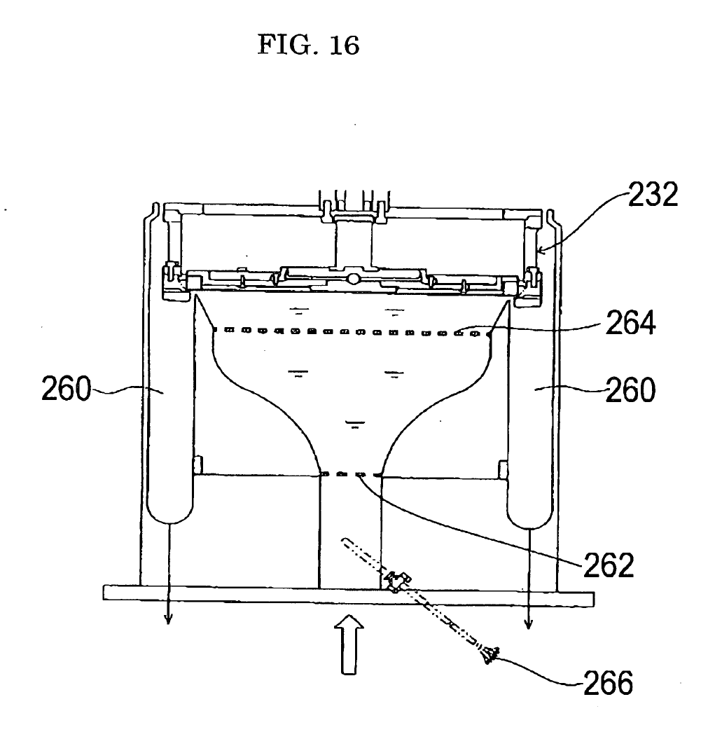

FIGS. 15 and 16 show a detail of the plating vessel 200. The plating vessel 200 is connected to a plating solution supply pipe 308 (shown in FIG. 17) at the bottom, and a plating solution recovering ditch 260 is provided at the upper end of a peripheral wall. Within the plating vessel 200, a couple of flow regulation plates 262, 264 are provided for stabilizing upward flow of the plating solution, and a thermometer 266 is provided at the bottom for measuring the temperature of the plating solution introduced to the plating vessel 200. Also, one or plural spurting nozzles 124a are provided on the peripheral wall for spurting a stopping solution of pH 6˜7.5 such as deionized water. The spurting nozzle opens above the liquid surface level within the plating vessel 200 toward a radial, slightly upward direction. The substrate W held by the head portion 232, after plating, is halted at a position above the plating solution surface level and the stopping solution is spurted from the spurting nozzle toward the substrate W to rapidly cool the substrate W to thereby prevent further progress of plating reaction caused by residual plating solution on the substrate W.

A plating vessel cover 270 is provided at the top of the plating vessel 200 to cover the top opening of the plating vessel 200. The cover 270 closes the aperture when the plating vessel 200 is not operated so as to prevent useless evaporation of the plating solution within the plating vessel 200. The cover 270 comprises a nozzle plate 124 on the upper surface for spurting a rinsing liquid such as deionized water toward the substrate W.

The plating vessel 200 is connected to a plating solution supply pipe 308 at the bottom, as shown in FIG. 17, extending from the plating solution reservoir tank 302 and comprising a plating solution supply pump and a three way valve 138. Thus, during plating, the plating solution is supplied to the plating vessel 200 from the bottom and the solution overflowed to the plating solution recovering ditch 260 is recovered to the plating solution reservoir tank 302 for circulation. One discharge port of the three way valve 138 is connected to a plating solution return pipe 312 which returns to the plating solution reservoir tank 302. By such construction, a plating solution circulating system is formed even when the plating vessel 200 is not operated, and by continuously circulating the plating solution in the plating solution reservoir tank 302, the solution is filtered to control the particles within the solution.

Especially, in this embodiment, the flow rates of the circulating plating solution can be individually set for the waiting period and the operation period by controlling the plating solution supply pump 304. For instance, the circulation flow rate for waiting period is 2˜20 L/min, and the circulation flow rate during operation period is set to 0˜10 L/min. Thus, a large circulation flow rate is set during waiting period, the temperature of the plating bath within the vessel is maintained constant, and a small flow rate is set during the plating operation so that a protection film 9 (plating film) of a uniform thickness can be deposited.

The thermometer 266 provided at the bottom of the plating vessel 200 measures the temperature of the plating solution introduced to the plating vessel 200, and based on the measured results, a heater 316 and a flow rate meter 318 are controlled as described below.

In this embodiment, the plating vessel 200 comprises a heating device 322 for indirectly heating the plating solution and an agitating pump 324 for circulating and agitating the plating solution within the reservoir tank 302. The heating device 322 comprises the heater 316 provided separate from the plating vessel 200, for heating water as a heating medium, the flow rate meter 318, and a heat exchanger 320 arranged within the plating vessel 200. The heating medium water is raised of its temperature by the heater 316 and sent to the heat exchanger 320 after passing through the flow rate meter 318 so as to heat the plating solution within the plating vessel 200 indirectly. This is provided because, in a plating process, the plating solution are often used at a temperature as high as 80° C. In the above mentioned process, contaminant are prevented from being introduced to the plating solution, which is very contaminant sensitive, compared to a conventional inline heating system.

In the embodiment, the plating solution temperature is set so that when it contacts with substrate W, the temperature of the substrate W becomes 70˜90° C., and the deviation of the temperature is not more than ±2° C.

In this electroless plating unit 22, the plating solution within the plating vessel 200 is circulated while the substrate W head 204 is at an elevated position and the head portion 232 holds the substrate W through suction force. When the plating process is to start, the cover 270 of the plating vessel 200 is opened, the substrate head 204 is lowered while being rotated, and the substrate W held by the head portion 232 is immersed into the plating solution within the plating vessel 200.

Then, after immersing the substrate W for a predetermined period, substrate head 204 is elevated and withdrawn from the plating solution, and, when necessary, a stopping solution such as deionized water is spurted from the spurting nozzle 268 toward the substrate W to rapidly cool the substrate W. Then the substrate head 204 is further elevated to bring the substrate W above the plating vessel 200 and stop rotation of the substrate head 204.

Then the top opening of the plating vessel 200 is covered by the plating vessel cover 270, and the substrate head 204, is rotated while spurting a rinsing liquid such as deionized water from the spurting nozzle 268 to wash the substrate W.

After cleaning the substrate W, the rotation of the substrate head 204 is stopped, and the substrate head 204 is elevated to withdraw the substrate W above the cleaning vessel. The substrate head 204 is further moved to a delivery position and transfers the substrate W to the following process stage.

The electroless plating unit 22 comprises a plating solution composition analyzer 330 for analyzing the composition of the plating solution reserved by the plating unit, as shown in FIG. 17, by using a process such as absorptiometry, titration, or electrical chemical measurement method.

The plating solution composition analyzer 330 uses: absorptiometry, ionic chromatograph, capillary electrophoresis, or chelatometric titration analysis for measuring the Co ion or Ni ion concentration; capillary electrophoresis for measuring a tungsten converted concentration for tungstic acid ions and/or tungstic phosphoric acid ions; oxidation-reduction titration or capillary electrophoresis for measuring the hypophosphorous acid ion, alkylamineborane, and/or NaBH₄ concentration; chelatometric titration or capillary electrophoresis for measuring the chelating agent concentration; and an electrode method or neutralization titration for measuring pH, for example. The above mentioned tungsten converted concentration can be calculated from the Co ion or Ni ion consumption.

A component replenish unit is provided for replenishing components which becomes short through the plating process based on the analyzed result. The component replenish replenishes components such as: Co ions or Ni ions; tungstic acid ions and/or tungstic phosphoric acid ions; hypophosphorous acid ions and/or alkylamineborane; and chelating agent by supplying the plating solution with a solution including respective component, or correct pH variation by supplying the plating solution with a pH adjuster, for example.

The plating solution reservoir tank 302 is provided with a level sensor 342 for sensing the surface level of the plating solution in the tank 302 to thereby calculate decreased amount of the plating solution through water evaporation, so that, based on the output signal of the level sensor 342, deionized water is supplied from the component replenish unit 340 to the plating solution to make up a shortage of water within the plating solution.

The plating solution reservoir tank 302 is further provided with a film measuring unit 346 comprising a quartz resonator 344 immersed within the plating solution for measuring the deposition rate of the protective film by utilizing the fact that, as the electrolessly plated film is deposited on the quartz resonator 344, oscillation frequency of the quartz resonator 344 attenuates. The film measuring unit 346 makes it possible to measure the deposition rate in situ.

By measuring the deposition rate during deposition of the protective film, it is recognizable if the actual deposition rate is a predetermined value. If it is recognized that the deposition rate is not the predetermined value, the plating period can be adjusted based on the measurement as required, so that the metal or alloy film of a predetermined thickness can be repeatably deposited.

The plating solution composition analyzer 330 also comprises a dissolved oxygen meter 332 for measuring concentration of the dissolved oxygen within the plating solution contained in the plating unit by using an electrical chemical process, for instance. Therefore, based on the indication of the dissolved oxygen meter 332, dissolved oxygen concentration in the plating solution can be controlled constant by using deaeration, nitrogen blowing, or other like method. This method can eventually enhances repeatability of the plating process.

When using the plating solution repeatedly, specific components accumulate in the plating solution by being introduced from the outer source or decomposition of the plating solution components, resulting in lower plating repeatability or deterioration of the film properties. Thus, by providing a device for selectively removing such specific components, a longer solution life and good repeatability of plating process can be realized.

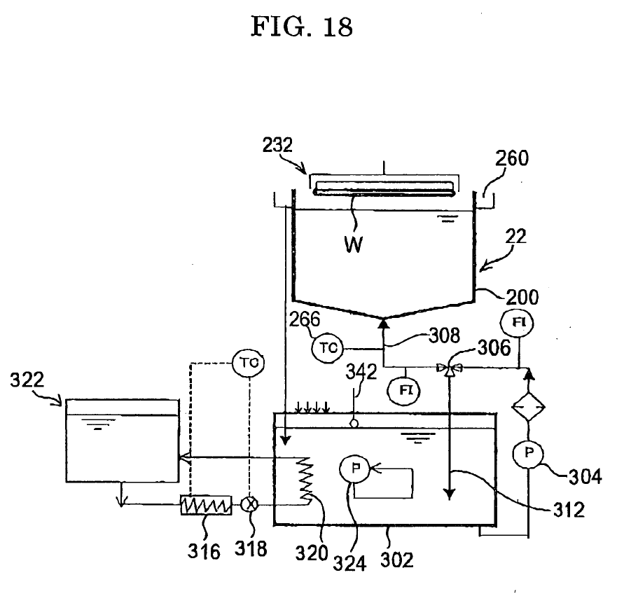

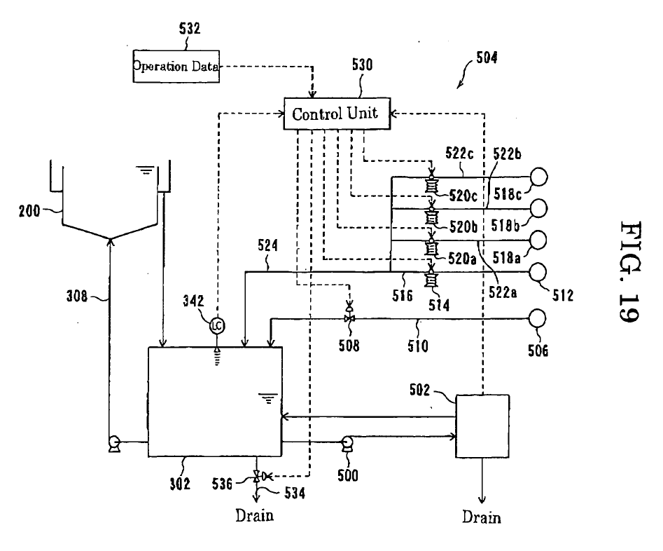

FIGS. 18 and 19 show a plating vessel 200 according to another embodiment of the present invention. The same or similar construction with regard to the embodiment shown in FIG. 17 is depicted by the same numeral and explanation is omitted. In order to control the film property or film thickness constant, it is necessary to maintain the composition of effective components within the plating solution. In the electroless plating process, various factors function to fluctuate quality and quantity of the plating solution as follow.

1. Deionized water used for rinsing the substrate W in a preprocess and is brought to the plating vessel 200.

2. Water loss due to evaporation caused by heating of the plating solution.

3. Plating solution deposited on the substrate W and brought out of the plating vessel 200.

4. Plating solution consumed for analysis for plating solution concentration regulation.

5. Plating solution brought out of the system due to temporary maintenance operation such as exchange of filters.

Therefore, in order to compensate the fluctuation of qualities and quantities of the plating solution due to the above mentioned factors by supplying solutions such as deionized water, a bath solution containing all the necessary effective components at a prescribed concentration, or a makeup solution containing an individual or plural effective components for plating to the plating solution. Similar to the previous embodiment, the plating solution reservoir tank 302 comprises a level sensor 342 for measuring the surface level of the plating solution contained within the tank to calculate decreased plating solution quantity. The plating solution reservoir tank 302 is also provided, as shown in FIG. 19, with a solution composition analyzer 330 for sampling by a pump 500 and analyzing the solution components by a process such as absorptiometry, titration, or electrochemical measuring.

The solution composition analyzer 330 uses: absorptiometry, ionic chromatograph, capillary electrophoresis, or chelatometric titration analysis for measuring the Co ion or Ni ion concentration; capillary electrophoresis for measuring a tungsten converted concentration for tungstic acid ions and/or tungstic phosphoric acid ions; oxidation-reduction titration or capillary electrophoresis for measuring the hypophosphorous acid ion, alkylamineborane, and/or NaBH₄ concentration; chelatometric titration or capillary electrophoresis for measuring the chelating agent concentration; and an electrode method or neutralization titration for measuring pH, for example. The above mentioned tungsten converted concentration can be also calculated from the Co ion or Ni ion consumption.

Further, the processing apparatus comprises a component supply system 504 for arbitrarily supplying deionized water, a bath solution containing all or major necessary effective components at a prescribed concentration and a makeup solution containing an individual or plurality of effective components necessary for plating at a prescribed concentration.

The component supply system 504 comprises: a deionized water supply line 510 extending from deionized water source 506 and having shutoff valve 508; a bath solution supply line 516 extending from a bath solution source 512 having a supply pump 514; and, in this embodiment, three makeup solution supply lines 522a˜522c extending from respective makeup solution sources 518a˜518c having respective supply pumps 520a˜520c. These lines are connected to the plating solution reservoir tank 302. In this embodiment, the bath solution supply line 516 and the three makeup solution lines 522a˜522c are merged into a merge line 524 which is connected to the plating solution reservoir tank 302. However, these lines can be independently connected to the plating solution reservoir tank 302.

In this embodiment, the three makeup solution sources 512 are provided to respectively supply, for example; a makeup solution containing Co ions or Ni ions at a concentration not less than a prescribed value from the first source 518a; a makeup solution containing tungstic acid ions and/or tungstic phosphoric acid ions at a concentration not less than a prescribed value from the second source 518b; a makeup solution containing hypophosphorous acid ions and/or alkylamineborane, a chelating agent and a pH adjuster at a concentration not less than a prescribed value from the third source 518c, for example. These are for exemplifying purpose and not for limiting the invention.

The component supply system 504 comprises a control unit 530 to which the signals from the level sensor 342 and liquid composition analyzer 502 are inputted as well as operational data. The control unit 530 outputs control signals to individually control the shutoff valve 508 provided in the deionized water supply line 510, the supply pumps 514, 520a˜520c respectively provided in the bath solution supply line 516 and the makeup solution supply lines 522a˜522c, and the shutoff valve 536 provided in the drain pipe 534 connected to the plating solution reservoir tank 302.

The control unit 530 is installed with a program or algorism for accumulating data for concentrations of the effective components within the plating bath or quantity of the plating solution as parameters relative to the number of the processed substrates W or operation time to calculate optimized supply amount for at least one of deionized water, bath solution, or makeup solution. The controller unit is readily installed with necessary data such as an average amount brought out of the plating vessel 200 with one substrate or necessary total amount of plating solution for one analyzing process for determination of each effective component within the plating solution. The average brought out quantity can be determined by measuring the actual amount through an experimental plating process. Also the necessary total amount for analyzing can be derived from a flow rate meter provided in a sampling line for flowing sample plating solution from the plating solution reservoir tank 302 to the solution component analyzer 502, or can be inputted as a fixed value.

Next, a process for calculating an optimized amount of deionized water supplied to the plating solution by the control unit 530. The supply amount of deionized water is determined by subtracting the brought-out amount and/or the amount consumed for solution analysis from the total decrease of the plating solution. The supply amount of the deionized water is inherently the amount corresponding to evaporation resulting from heating of the plating solution. However, various other factors influence the plating solution amount, and there is no method for directly measuring the evaporation amount. These other factors include brought-in solutions such as deionized water deposited on the substrate W which was used for rinsing as a pretreatment, or deionized water used for rinsing the substrate W in the plating vessel 200 after plating. The brought-in solutions cancel the evaporated water and categorized as the total decrease of the plating solution. The amount of the brought-out plating solution and those consumed for solution analysis belongs to decrease of the plating solution itself, and if this is compensated by adding deionized water, the concentration of the plating solution will be lowered. Therefore, these amounts should be excluded from the deionized water supply amount. Thus, the amount of deionized water supply is calculated by subtracting those from the total decrease.

Specifically, deionized water supply amount: VsupDIW (mL) is calculated from an evaporated deionized water amount: Veva (mL), and a diluted or added deionized water amount through rinsing or cleaning: Vwaf (mL), according to the following equation.

ΣVsupDIW=(Veva−Vwaf)

The evaporated deionized water amount: Veva (mL), and the diluted or added deionized water amount: Vwaf (mL) are calculated from the following equations.

Veva=UeVa×δt

Vwaf=Pwaf×Nwaf

wherein, Ueva (mL/min) is a evaporation amount per unit time depending on the bath temperature, δt is accumulated time since last time the deionized water is supplied, Pwaf (mL/str) is a total rinsing liquid (deionized water) supply per one substrate, and Nwaf is an accumulated number of substrates W processed since the last time deionized water was supplied.

However, it is difficult to directly obtain evaporated deionized water amount. Therefore, in this embodiment, the following equations are used for obtaining deionized water supply amount: VsupDIW (mL).

VsupDIW=Vdec−(VMsam+VMwaf) (1)

VMsam=pMsam×Nsam

VMwaf=pMwaf×Nwaf

wherein, Vdec (mL) is a decreased amount of the plating solution derived from the liquid level difference within the plating solution reservoir tank 302, VMsam (mL) is a total amount of plating solution consumed in the solution composition analyzer 502, VMwaf (mL) is a brought-out amount of plating solution from the system during plating, ρMsam (mL) is a consumption for one analysis in the solution composition analyzer 502, Nsam is the number of analysis since last time the solution adjustment was conducted, ρMwaf (mL) is a brought-out amount of plating solution per one substrate, and Nwaf is an accumulated number of substrates W processed since last time the solution adjustment was conducted.

A regulation range for concentration of the electroless plating solution differs depending on the plating process, and generally, it is necessary to control variance within ±10%. When obtaining the total decrease of the plating solution by measuring the liquid level decrease, the level sensor 342 can offer a ±0.5 mm precision. This makes possible to control the amount of the plating solution, depending on the size of the plating vessel 200, within ±0.5% for the plating vessel 200 containing 100 L of plating solution. Thus, by measuring decrease of the surface level of the plating solution reservoir tank 302, concentration fluctuation due to water evaporation can be controlled within a prescribed range.

Since the plating solution brought out of the plating vessel 200 along with the substrate W or the plating solution consumed for analysis corresponds to a loss of plating solution itself, so that a bath solution containing all of the necessary effective components at prescribed concentrations is supplied at an amount corresponding to the decreased amount. It is possible to supply deionized water and one or more makeup solutions respectively containing only specific component. This method may require further concentration adjustment to thereby make the process complicate. When supplying the bath solution, amount can be calculated by summing an accumulated brought-out amount and an accumulated analyzer consumption. The accumulated brought-out amount is calculated by multiplying the average brought-out amount per one substrate with the number of processed substrates W, and the accumulated analyzer consumption is calculated by multiplying the average analyzer consumption with the number of analyses. The above calculation is expressed by the following equation for the bath solution supply amount: ΣVMsup (mL), and can be computerized by establishing a suitable algorism.

ΣVMsup=(VMsam+VMwaf) (2)

The makeup solution is used when concentration of a specific effective component is different from the prescribed concentration based on a solution analysis result. It there is any shortage, a necessary amount for recovering prescribed concentration will be calculated and supplied to the plating solution to maintain the prescribed concentration of each plating solution component.

Next, supply of the deionized water, bath solution, and makeup solution are explained in detail. To start with, decrease of the plating solution within the plating vessel 200 is measured by the level sensor 342 and the output signal is inputted to the control unit 530. The control unit 530 calculates deionized water supply amount VsupDIW (mL) based upon the sum of: output signal of the level sensor 342; operational data signal; a readily inputted taken-out quantity with a single substrate W; and a determination quantity necessary for one determination of every effective components, in accordance with the above equation. Then, the control unit 530 opens the shutoff valve 508 in the deionized water supply line 510 to an extent corresponding the calculated deionized water supply amount to supply deionized water to the plating solution within the plating solution reservoir tank 302.

Subsequently, the bath solution supply quantity is calculated in the same manner in accordance with the equation (2) and the supply pump 514 is operated to an extent corresponding the calculated bath solution supply amount to supply bath solution to the plating solution within the plating solution reservoir tank 302.

After supplying the deionized water and bath solution, the plating solution within the plating solution reservoir tank 302 is sampled and analyzed by the solution component analyzer 502 unit. Based upon the analyzed result, any component in short is designated and the supply pumps 520a˜520c in the makeup solution supply lines 522a˜522c is driven to supply the component in short to the plating solution within the plating solution reservoir tank 302. This concentration adjusting process by supplying makeup solution is inherently for compensating the consumed effective components through plating process. Therefore, it is appropriate to do this process after compensating evaporated water with deionized water and taken out bath solution with bath solution to regulate the composition other than those consumed for plating.

Generally, the electroless plating deposits films in a plating solution at a temperature higher than the room temperature. The deposition rate for the electroless plating is highly temperature dependent, so that it is necessary to control the plating solution temperature within a range for depositing films with good repeatability. If the deionized water, bath solution, or makeup solution at the room temperature are supplied to the plating solution, the solution temperature will temporarily be lowered. Thus, in the present embodiment of the invention, the control unit 530 restricts the total amount for those solutions supplied at one time not more than 2.0 L, so that, for example, when the plating solution temperature is 70° C. and the effective volume of the plating solution reservoir tank 302 is 100 L, the temperature lowering is maintained within 1° C.

The above described process for supplying the deionized water and bath solution is for compensating decrease of the plating solution based on routine plating operation, and decrease of the plating solution can occur due to other than routine plating operation such as exchange of filters. If the case includes such non-routine factors, the amount of supply should include those corresponding to the decrease due to the non-routine factors.

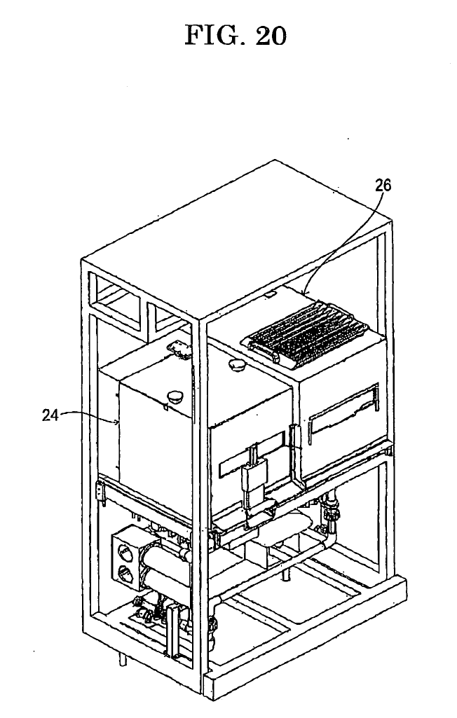

FIG. 20 shows details of the post-process unit 24 and drying unit 26 shown in FIG. 2. The post-process unit 24 comprises a roller brush and the dryer unit comprises a spin dryer.

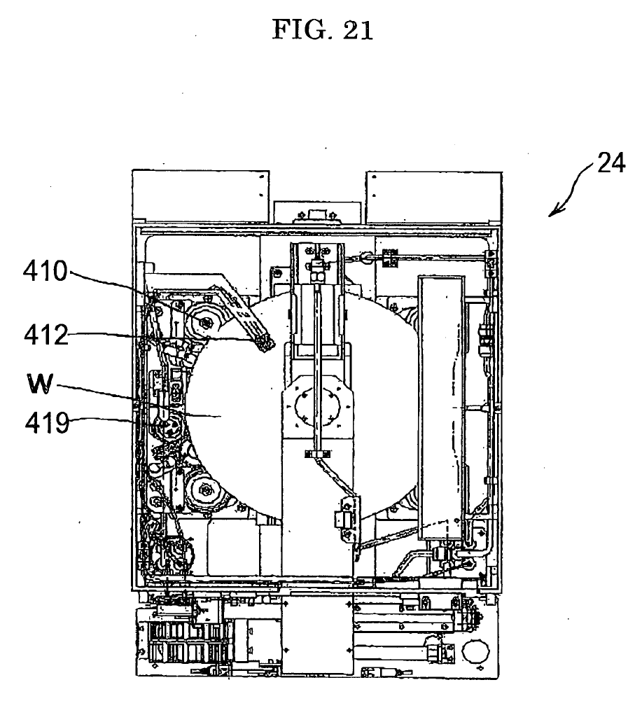

FIG. 21 shows the preprocess unit. The preprocess unit is a unit for forcibly removing particles or unnecessary matters from the substrate W with the roller brushes, and comprises a plurality of rollers 410 for engaging with the periphery of the substrate W to hold it; a chemical agent nozzles 412 for supplying a processing solution, through two lines in this embodiment, to the surface of the substrate W; and a deionized water nozzle (not shown) for supplying deionized water, through one line in this embodiment, to the rear surface of the substrate W.

With such construction, the post-process unit 24 holds the substrate W with the rollers 410, rotates it by actuating a roller drive motor, and supplies prescribed solutions to both surfaces of the substrate w from the chemical agents nozzles 412 and deionized water nozzles concurrently, and pushing the upper and lower roller brushes or roller sponges (not shown) on the upper and lower surfaces with an appropriate pressure to clean the substrate W. The roller sponges can be independently rotated for more efficiently cleaning.

The post-process 24 unit is provided with a sponge (PFR) 419 rotatable while contacting with the edge or periphery of the substrate W for scrubbing and cleaning the area.

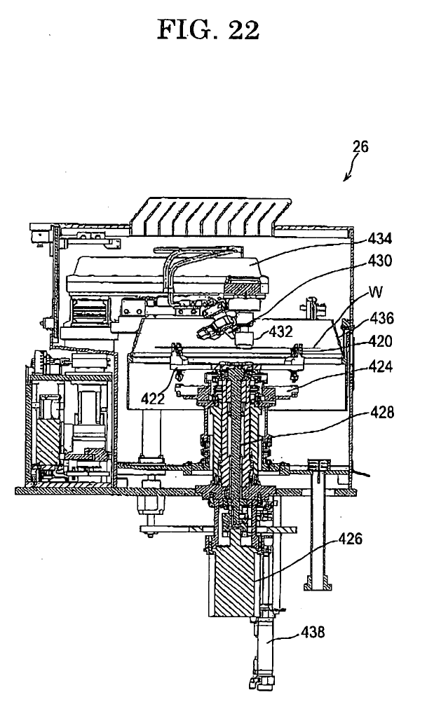

FIG. 22 shows the dryer unit 26. The dryer unit 26 is a unit for firstly doing chemical cleaning and deionized water cleaning, and then completely drying the cleaned substrate W with spindle rotation, and comprises a substrate stage 422 having a cramp assembly 420 for holding the edge of the substrate W, and an elevation plate 424 for attaching or detaching the substrate W by opening or closing the cramp assembly 420. The substrate stage is connected to the upper end of the spindle 428 which is rotated at a high speed by activation of a spindle rotation motor 426.

Above the substrate W held by the cramp assembly, a mega-jet nozzle 430 of a specific design having an ultrasonic wave transmitter for transmitting ultrasonic wave to deionized water passing therethrough to enhance its cleaning effect, and a rotatable, pencil-shaped cleaning sponge 432 are arranged by being attached to the tip end of a swing arm 434. Thus, by holding and rotating the substrate W with the cramp assembly, supplying deionized water from the mega-jet nozzle 430, and scrubbing the surface of the substrate W with the cleaning sponge 432 while swinging the swing arm 434, the substrate surface is cleaned. A deionized water nozzle is also provided beneath the substrate (not shown) for concurrently spurting deionized water to clean the rear surface.

The cleaned substrate W is spin-dried by rotating the spindle 428 at a high speed.

A cleaning cup 436 is provided to surround the substrate w held by the cramp assembly 420 for preventing variance of the process liquid, which is elevatable by a cup elevation cylinder 438. The dryer unit 26 may also be equipped with a “cavitation jet” function utilizing cavitation mechanism.

When using a hydrogen-dissolved water or electrolyzed cathodic water as the rinsing liquid, respective units for dissolving hydrogen into or electrolyzing deionized water can be provided to supply these solutions to the substrate W.

Although the above described embodiments are exemplified for cases using a Co—W—P alloy film for the plating film, it is possible to use plating films made of alloys such as Co—P, Ni—P, or Ni—W—P. Also, the interconnect can be made of copper alloys, silver, silver alloys, gold, or gold alloys, instead of copper.

Although the above embodiments describe the case where the invention is applied to the formation of the plating film on the surface of a filled-in interconnect deposited on the substrate W, it is possible to apply the invention to form a conductive film or plating film, which functions to prevent the interconnect material from diffusing into interlayer insulative films, on the lower or lateral surface of the interconnect in the same manner as above since high accuracy is required in depositing the plating films described above, with regard to film thickness, film properties, and selectivity of the plating, it is necessary to control time between each step of the process. This can be accomplished easily with the processing apparatus of the embodiment, because the apparatus provides every unit necessary to perform all the steps in the same apparatus.

If chemical agents or plating solution remain on the surface of the substrate W even after the chemical process or plating process, it will adversely affect uniformity of the properties within the surface of the plating film or film properties of the interconnect such as electric resistance. By the apparatus of the embodiment, chemical processing and deionized water rinsing are performed in the same unit to rapidly remove the remaining chemical agents or plating solution to manufacture semiconductor devices with a high yield as well as to reduce necessary footprint for the apparatus.

By adopting a spurting method for chemical agents or plating solution, fresh liquid can be constantly supplied in a uniformly dispersed state onto the substrate W surface, which also facilitate to shorten the necessary processing time. By adjusting the spurting point or opening of the nozzle, uniformity of the processing within the surface area can be easily improved. However, other methods such as immersing can be used when a moderate processing of the substrate surface is necessary.

Since a certain limit exists for spurting angle of a single nozzle, it can cover a limited area. If the spurting distance is too short, a large number of nozzles are required for covering the whole surface area of the substrate W, and if the distance is too long, a high performance compressor is necessary and the total height of the apparatus will be large. Thus, the number of the spurting nozzles 124a for a single step is preferably 1˜25, for example, and a preferable distance between the spurting nozzle 268 and the substrate W is 10˜150 mm, for example. A preferable flow rate of the chemical agents or plating solution from a single is 0.2˜1.2 L/min, and a preferable spurting pressure is 10˜100 kPa.

The present invention has been explained with reference to the embodiments as described above, this is not meant for limiting the scope of the invention. The present invention can be variously modified within its spirit.

What is claimed is:

1. A method of processing a substrate having a metal layer formed on a surface of said substrate comprising:
preprocessing a surface of said metal layer;
depositing a protective film selectively on a surface of said metal layer by an electroless plating process;
cleaning said substrate after depositing said protective film;
drying said substrate after cleaning; and
repeating said preprocessing, depositing, cleaning, and drying a plurality of times to process a plurality of substrate,
wherein deposition rate in said deposition process is 10˜600 Å/min, and a variance of deposition rate for said plurality of substrate is within ±10%.

2. The method of claim 1, wherein said metal layer is an exposed surface of a filled-in interconnect deposited on bottom and side surfaces of a trench formed on a surface of said substrate, or on a surface of said substrate.

3. The method of claim 1, wherein said metal layer comprises copper, a copper alloy, silver, a silver alloy, Ti, Ta, W, Ru, and a compound thereof.

4. The method of claim 1, wherein said protective film comprises at least one of cobalt, a cobalt alloy, nickel, a nickel alloy.

5. The method of claim 4, wherein said protective film comprises at least (1) cobalt or nickel, (2) tungsten or molybdenum, and (3) phosphorous or boron.

6. The method of claim 1, wherein said protective film is deposited by making said substrate contact with a plating solution for adjusting the temperature of said substrate at 70˜90° C.

7. The method of claim 6, wherein variance of the temperature of said plating solution is controlled within ±2° C.

8. The method of claim 6, wherein decrease of said plating solution due to evaporation is compensated to control the decrease of plating solution within ±10% of initial quantity of said plating solution.

9. The method of claim 8, wherein decrease of said plating solution is quantified by measuring liquid level within a plating solution reservoir tank, and shortage of water is compensated by supplying deionized water to said plating solution.

10. The method of claim 1, wherein said electroless plating is performed by using a plating solution containing Co ions or Ni ions of 0.01˜0.1 mol/L.

11. The method of claim 10, wherein variance of Co ion or Ni ion concentration is maintained within ±20%.

12. The method of claim 9, wherein Co ion or Ni ion concentration within the plating solution is measured by an absorptiometry analyzer, an ion chromatograph analyzer, a capillary electrophoresis analyzer, or a chelatometric titration analyzer, and shortage of Co ion or Ni ion is compensated by replenishing a solution containing Co ions or Ni ions.

13. The method of claim 1, wherein said electroless plating is performed by using a plating solution containing a concentration of tungstic acid or molybdic acid ions and/or tungsten phosphoric acid or molybdenum phosphoric acid ions of 1.5˜30.0 g/L as converted to tungsten or molybdenum.

14. The method of claim 13, wherein variance of said tungsten or molybdenum converted concentration is controlled within ±40%.

15. The method of claim 13, wherein said tungsten or molybdenum converted concentration is measured by a capillary electrophoresis analyzer, or calculated from Co ion or Ni ion consumption, and shortage of tungsten or molybdenum converted concentration is compensated by replenishing a solution containing tungstic acid or molybdic acid ions and/or tungsten phosphoric acid or molybdenum phosphoric acid ions.

16. The method of claim 1, wherein said electroless plating is performed by using a plating solution containing hypophosphorous acid ions, alkylamineborane, and/or NaBH₄ of 0.05-0.3 mol/L.

17. The method of claim 16, wherein variance of said hypophosphorous acid ions, alkylamineborane, and/or NaBH₄ concentration is controlled within ±40%.

18. The method of claim 17, wherein said hypophosphorous acid ions, alkylamineborane, and/or NaBH₄ concentration is measured by an oxidation-reduction titration analyzer or a capillary electrophoresis analyzer, and shortage of said hypophosphorous acid ions, alkylamineborane, and/or NaBH₄ concentration is compensated by replenishing a solution containing hypophosphorous acid ions, alkylamineborane, and/or NaBH₄.

19. The method of claim 1, wherein said electroless plating is performed by using a plating solution containing a chelating agent of 0.05˜0.5 mol/L.

20. The method of claim 19, wherein variance of said chelating agent concentration is controlled within ±30%.

21. The method of claim 19, wherein said chelating agent concentration is measured by a chelatometric titration analyzer or a capillary electrophoresis analyzer, and shortage of aid chelating agent concentration is compensated by replenishing a solution containing said chelating agent.

22. The method of claim 1, wherein said electroless plating is performed by using a plating solution containing a pH buffer and an alkaline agent, and pH of the plating solution is set at 8˜10.

23. The method of claim 22, wherein variance of pH is controlled within ±0.2.

24. The method of claim 19, wherein pH of said plating solution is measured by an electrode method or neutralization titration, and fluctuation of pH is compensated by replenishing a solution containing a pH adjuster.

25. The method of claim 1, wherein deposition rate of said protective film is measured in said electroless plating process.

26. The method of claim 25, wherein deposition rate of said alloy film is measured by immersing a quartz resonator in a plating bath, and by utilizing a phenomenon that oscillation frequency of said quartz resonator attenuates as electroless plating film deposits on said quartz resonator.

27. The method of claim 25, wherein process time for plating is adjusted based on measured result of said deposition rate.

28. A apparatus for processing a substrate having a filled-in interconnect formed on a surface of said substrate, said filled-in interconnect having bottom and side surfaces or an exposed surface, said apparatus comprising:
a preprocessing unit for preprocessing a surface of said substrate;
an electroless plating unit for depositing a protective film selectively on said bottom and side surfaces or said exposed surface of said filled-in interconnect by an electroless plating process while deposition rate in said deposition process is controlled 10˜200 Å/min, and a variance of deposition rate for said substrate is controllable within ±10%.

29. The apparatus of claim 28, wherein said electroless plating unit comprises a liquid temperature sensor for sensing a plating solution and a liquid temperature control portion for controlling temperature of said plating solution.

30. The apparatus of claim 28, wherein said electroless plating unit comprises a plating solution reservoir tank for reserving a plating solution, and a liquid level sensor for measuring decreased amount of said plating solution due to evaporation by measuring liquid surface level of said plating solution.

31. The apparatus of claim 28, further comprising a plating solution composition analyzer for analyzing composition of a plating solution contained in said electroless plating unit.

32. The apparatus of claim 28, further comprising a component supply unit for supplying a component in short within a plating solution contained in said electroless plating unit.

33. The apparatus of claim 1, further comprising a deposition rate measuring portion for measuring deposition rate in said electroless plating process.

34. A method of processing a substrate comprising:
preprocessing a surface of said substrate;
depositing a metal or alloy film on at least a part of a surface of said substrate by an electroless plating process using a plating solution;
cleaning said substrate after depositing said film;
drying said substrate after cleaning; and
supplying at least three supply solutions consisting of:
a deionized water;
a bath solution containing necessary components for plating; and
a makeup solution containing at least one effective component necessary for plating,
wherein said at least three supply solutions are supplied while each supply amount is individually controlled.

35. The method of claim 34, wherein said bath solution is supplied subsequently after said deionized water is supplied.

36. The method of claim 35, wherein said makeup solution is supplied subsequently after said deionized water and/or said bath solution is supplied.

37. The method of claim 35, wherein said deionized water is supplied at an amount calculated by subtracting a brought-out amount by said substrate and/or analysis consumption amount used for composition analysis from a total decrease amount of said plating solution.

38. The method of claim 35, wherein said bath solution is supplied at an amount corresponding to a brought-out amount by said substrate and/or analysis consumption amount used for composition analysis.

39. The method of claim 35, wherein said makeup solution is supplied by analyzing concentration of said effective component decreased after plating, and supply makeup solution at an amount necessary to recover a prescribed concentration.

40. The method of claim 37, wherein said total decrease amount is obtained by measuring decreased liquid level of said plating solution within said plating solution reservoir tank.

41. The method of claim 37, wherein said brought-out amount is calculated as a product of an average brought-out amount per a single substrate and the number of processed substrate after the last solution supply.

42. The method of claim 37, wherein said analysis consumption amount is calculated as a product of an average analysis consumption amount per a single analysis and the number of analyses.

43. The method of claim 37, wherein said at least three supply solutions are supplied while each supply amount per unit time is limited to control variation of temperature or concentration of said plating solution within a prescribed range.

44. An apparatus for processing a substrate comprising:
a preprocessing unit for preprocessing a surface of said substrate;
an electroless plating unit for depositing a metal or alloy film on a surface of said substrate by an electroless plating process using a plating solution;
a plating solution reservoir tank for reserving, supplying to said plating unit, and circulating between said plating unit;
a component supply system for supplying at least three supply solutions consisting of a deionized water, a bath solution containing necessary components for plating, and a makeup solution containing at least one effective component necessary for plating; and
a solution component analyzer for analyzing component in said plating solution.

45. The apparatus of claim 44, wherein said component supply system comprises a control unit for individually controlling said at least three supply solutions.

46. The apparatus of claim 45, wherein said control unit accumulates data for concentrations of said effective components within the plating bath or quantity of said plating solution as parameters relative to the number of processed substrates or operation time to calculate optimized supply amount for at least one of said deionized water, bath solution, or makeup solution.

47. The apparatus of claim 46, wherein said controller unit is installed with a program to which at least one data selected from a data group is inputted, said data group includes: a data of decreased amount of the plating solution within said plating solution reservoir tank; an analysis data of effective component concentration within said plating solution; a data of an average amount consumed for one analyzing process for determination of said effective component; a data of an average brought-out amount of the plating solution with one substrate; a data of the total number of the substrate processed or the number per unit time.
